(19) United States
(12) Patent Application Publication
(10) Pub. No.: US 2024/0279399 A1
(43) Pub. Date: Aug. 22, 2024

(54) POLYMERS FOR USE IN ELECTRONIC DEVICES

(71) Applicants: DUPONT ELECTRONICS, INC., Wilmington, DE (US); ROHM AND HAAS ELECTRONIC MATERIALS (SHANGHAI) CO., LTD., Shanghai (CN)

(72) Inventors: Yang Li, Shanghai (CN); Yuchun Liu, Shanghai (CN); Grace Yeh, Wilmington, DE (US); Nora Radu, Wilmington, DE (US); Rebecca Siegelman, Wilmington, DE (US); Christina Older, Wilmington, DE (US); Greg Hostetler, Wilmington, DE (US); Adam Fennimore, Wilmington, DE (US)

(21) Appl. No.: 18/567,882

(22) PCT Filed: Jun. 7, 2021
(86) PCT No.: PCT/CN2021/098525

§ 371 Date: Dec. 7, 2023

(51) Int. Cl. C08G 73/10; C08J 5/18; C08K 5/50; C08K 5/521; C08K 5/5313; C08K 5/5333; C08K 5/5397; H10K 77/10

(52) U.S. Cl. CPC C08G 73/1042; C08G 73/1053; C08J 5/18; C08K 5/50; C08K 5/521; C08K 5/5313; C08K 5/5333; C08K 5/5397; H10K 77/111; C08J 2379/08

(57) ABSTRACT

Disclosed is a polyimide film prepared from a liquid composition comprising a liquid composition comprising (a) a polyamic acid having a repeat unit structure of Formula I

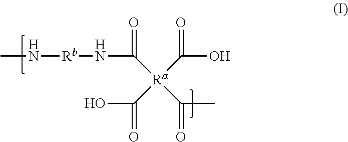

wherein R^{a} is the same or different at each occurrence and represents one or more tetracarboxylic acid component residues and R^{b} is the same or different at each occurrence and represents one or more diamine component residues, (b) one or more phosphorous-containing additivesm and (c) a high-boiling aprotic solvent. Also disclosed are processes for making the film and uses of the film in electronic devices.

### BACKGROUND INFORMATION

### Field of the Disclosure

The present disclosure relates to novel liquid compositions. The disclosure further relates to polyimide films made from such compositions, methods for preparing such polyimide films, and electronic devices having at least one layer comprising these polyimide films.

### Description of the Related Art

Materials for use in electronics applications often have strict requirements in terms of their structural, optical, thermal, electronic, and other properties. As the number of commercial electronics applications continues to increase, the breadth and specificity of requisite properties demand the innovation of materials with new and/or improved properties. Polyimides represent a class of polymeric compounds that has been widely used in a variety of electronics applications. They can serve as a flexible replacement for glass in electronic display devices provided that they have suitable properties. These materials can function as a component of Liquid Crystal Displays (“LCDs”), where their modest consumption of electrical power, light weight, and layer flatness are critical properties for effective utility. Other uses in electronic display devices that place such parameters at a premium include device substrates, substrates for color filter sheets, cover films, touch screen panels, and others.

A number of these components are also important in the construction and operation of organic electronic devices having an organic light emitting diode (“OLED”). OLEDs are promising for many display applications because of their high power conversion efficiency and applicability to a wide range of end-uses. They are increasingly being used in cell phones, tablet devices, handheld/laptop computers, and other commercial products. These applications call for displays with high information content, full color, and fast video rate response time in addition to low power consumption.

Polyimide films generally possess sufficient thermal stability, high glass transition temperature, and mechanical toughness to merit consideration for such uses. Also, polyimides generally do not develop haze when subject to repeated flexing, so they are often preferred over other transparent substrates like polyethylene terephthalate (PET) and polyethylene naphthalate (PEN) in flexible display applications.

The traditional amber color of polyimides, however, precludes their use in some display applications such as color filters and touch screen panels since a premium is placed on optical transparency. Further, polyimides are generally stiff, highly aromatic materials; and the polymer chains tend to orient in the plane of the film/coating as the film/coating is being formed. This leads to differences in refractive index in the parallel vs. perpendicular directions of the film (birefringence) which produces optical retardation that can negatively impact display performance.

Further, the processing of polyimides into electronic devices often exposes them to additional stresses in terms of temperature, environment, strain, etc. Such exposure can lead to the formation of defects and imperfections that render a particular film unusable in a given device. Not only is the polyimide film itself compromised, but the entire device can be rendered useless so as to require rework, replacement, etc.

If polyimides are to find additional applications in the displays market, a solution is needed to maintain their desirable properties throughout processing, while at the same time improving their optical transparency and reducing the amber color and birefringence that leads to optical retardation.

There is thus a continuing need for improved polymeric materials like polyimide films that are suitable for use in electronic devices.

### SUMMARY

There is provided a liquid composition containing
(a) a polyamic acid having a repeat unit structure of Formula I

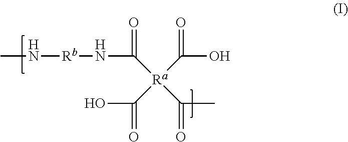

wherein R^{a} is the same or different at each occurrence and represents one or more tetracarboxylic acid component residues and R^{b} is the same or different at each occurrence and represents one or more diamine residues; (b) one or more phosphorous-containing additives; and
(c) a high-boiling aprotic solvent.

There is further provided a polyimide film containing a repeat unit structure of Formula II

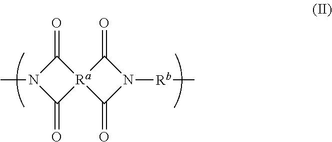

wherein R^{a} is the same or different at each occurrence and represents one or more tetracarboxylic acid component residues and R^{b} is the same or different at each occurrence and represents one or more diamine residues; and further wherein the polyimide film is prepared according to a method comprising the following steps in order and without repeating: coating a polyamic acid solution comprising one or more tetracarboxylic acid components and one or more diamine components in a high-boiling, aprotic solvent onto a matrix; soft-baking the coated matrix; treating the soft-baked coated matrix at a plurality of pre-selected temperatures for a plurality of pre-selected time intervals.

There is further provided a flexible replacement for glass in an electronic device wherein the flexible replacement for glass is the above-described polyimide film.

There is further provided an electronic device having at least one layer comprising the above-described polyimide film.

There is further provided an organic electronic device, such as an OLED, wherein the organic electronic device contains a flexible replacement for glass as disclosed herein.

The foregoing general description and the following detailed description are exemplary and explanatory only and are not restrictive of the invention, as defined in the appended claims.

### BRIEF DESCRIPTION OF THE DRAWINGS

Embodiments are illustrated in the accompanying figures to improve understanding of concepts as presented herein.

FIG. 1 includes an illustration of one example of a polyimide film that can act as a flexible replacement for glass.

FIG. 2 includes an illustration of one example of an electronic device that includes a flexible replacement for glass.

Skilled artisans appreciate that objects in the figures are illustrated for simplicity and clarity and have not necessarily been drawn to scale. For example, the dimensions of some of the objects in the figures may be exaggerated relative to other objects to help to improve understanding of embodiments.

### DETAILED DESCRIPTION

There is provided a polyamic acid having Formula I, as described in detail below.

There is further provided a liquid composition comprising (a) the polyamic acid having Formula I, (b) one or more phosphorous-containing additives, and, (c) a high-boiling, aprotic solvent.

There is further provided a polyimide whose repeat units have the structure in Formula II, as described in detail below.

There is further provided one or more methods for preparing a polyimide film wherein the polyimide film has the repeat unit of Formula II.

There is further provided a flexible replacement for glass in an electronic device wherein the flexible replacement for glass is a polyimide film having the repeat unit of Formula II.

There is further provided an electronic device having at least one layer comprising a polyimide film having the repeat unit of Formula II.

There is further provided an organic electronic device, such as an OLED, wherein the organic electronic device contains a flexible replacement for glass as disclosed herein.

Many aspects and embodiments have been described above and are merely exemplary and not limiting. After reading this specification, skilled artisans appreciate that other aspects and embodiments are possible without departing from the scope of the invention.

Other features and benefits of any one or more of the embodiments will be apparent from the following detailed description, and from the claims. The detailed description first addresses Definitions and Clarification of Terms, followed by the Liquid Composition, the Polyimide, the Methods for Preparing the Polyimide Films, the Electronic Device, and finally Examples.

### 1. Definitions and Clarification of Terms

Before addressing details of embodiments described below, some terms are defined or clarified.

As used in the “Definitions and Clarification of Terms”, R, R^{a}, R^{b}, R′, R″ and any other variables are generic designations and may be the same as or different from those defined in the formulas.

The term “additive” is intended to mean something that is added, as one substance to another, to alter or improve the general quality or to counteract undesirable properties of an overall collection of components. In some non-limiting embodiments, an additive is used at concentrations much less than those of the primary constituents of a composition or mixture.

The term “alignment layer” is intended to mean a layer of organic polymer in a liquid-crystal device (LCD) that aligns the molecules closest to each plate as a result of its being rubbed onto the LCD glass in one preferential direction during the LCD manufacturing process.

As used herein, the term “alkyl” includes branched and straight-chain saturated aliphatic hydrocarbon groups. Unless otherwise indicated, the term is also intended to include cyclic groups. Examples of alkyl groups include methyl, ethyl, propyl, isopropyl, isobutyl, secbutyl, tertbutyl, pentyl, isopentyl, neopentyl, cyclopentyl, hexyl, cyclohexyl, isohexyl and the like. The term “alkyl” further includes both substituted and unsubstituted hydrocarbon groups. In some embodiments, the alkyl group may be mono-, di- and tri-substituted. One example of a substituted alkyl group is trifluoromethyl. Other substituted alkyl groups are formed from one or more of the substituents described herein. In certain embodiments alkyl groups have 1 to 20 carbon atoms. In other embodiments, the group has 1 to 6 carbon atoms. The term is intended to include heteroalkyl groups. Heteroalkyl groups may have from 1-20 carbon atoms.

The term “aprotic” refers to a class of solvents that lack an acidic hydrogen atom and are therefore incapable of acting as hydrogen donors. Common aprotic solvents include alkanes, carbon tetrachloride (CCl4), benzene, dimethyl formamide (DMF), N-methyl-2-Pyrrolidone (NMP), dimethylacetamide (DMAc), and many others.

The term “aromatic compound” is intended to mean an organic compound comprising at least one unsaturated cyclic group having 4n+2 delocalized pi electrons. The term is intended to encompass both aromatic compounds having only carbon and hydrogen atoms, and heteroaromatic compounds wherein one or more of the carbon atoms within the cyclic group has been replaced by another atom, such as nitrogen, oxygen, sulfur, or the like.

The term “aryl” or “aryl group” a moiety formed by removal of one or more hydrogen (“H”) or deuterium (“D”) from an aromatic compound. The aryl group may be a single ring (monocyclic) or have multiple rings (bicyclic, or more) fused together or linked covalently. A “hydrocarbon aryl” has only carbon atoms in the aromatic ring(s). A “heteroaryl” has one or more heteroatoms in at least one aromatic ring. In some embodiments, hydrocarbon aryl groups have 6 to 60 ring carbon atoms; in some embodiments, 6 to 30 ring carbon atoms. In some embodiments, heteroaryl groups have from 4-50 ring carbon atoms; in some embodiments, 4-30 ring carbon atoms.

The term “alkoxy” is intended to mean the group —OR, where R is alkyl.

The term “aryloxy” is intended to mean the group —OR, where R is aryl.

Unless otherwise indicated, all groups can be substituted or unsubstituted. An optionally substituted group, such as, but not limited to, alkyl or aryl, may be substituted with one or more substituents which may be the same or different. Suitable substituents include alkyl, aryl, nitro, cyano, —N(R′)(R″), halo, hydroxy, carboxy, alkenyl, alkynyl, cycloalkyl, heteroaryl, alkoxy, aryloxy, heteroaryloxy, alkoxycarbonyl, perfluoroalkyl, perfluoroalkoxy, arylalkyl, silyl, siloxy, siloxane, thioalkoxy, —S(O)₂—, —C(═O)—N(R′)(R″), (R′)(R″)N-alkyl, (R′)(R″)N-alkoxyalkyl, (R′)(R″)N-alkylaryloxyalkyl, —S(O)ₛ-aryl (where s=0-2) or —S(O)ₛ-heteroaryl (where s=0-2). Each R′ and R″ is independently an optionally substituted alkyl, cycloalkyl, or aryl group. R′ and R″, together with the nitrogen atom to which they are bound, can form a ring system in certain embodiments. Substituents may also be crosslinking groups.

The term “amine” is intended to mean a compound that contains a basic nitrogen atom with a lone pair. The term “amino” refers to the functional group —NH₂, —NHR, or —NR₂, where R is the same or different at each occurrence and can be an alkyl group or an aryl group. The term “diamine” is intended to mean a compound that contains two basic nitrogen atoms with associated lone pairs. The term “aromatic diamine” is intended to mean an aromatic compound having two amino groups. The term “bent diamine” is intended to mean a diamine wherein the two basic nitrogen atoms and associated lone pairs are asymmetrically disposed about the center of symmetry of the corresponding compound or functional group, e.g. m-phenylenediamine:

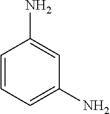

The term “aromatic diamine residue” is intended to mean the moiety bonded to the two amino groups in an aromatic diamine. The term “aromatic diisocyanate residue” is intended to mean the moiety bonded to the two isocyanate groups in an aromatic diisocyanate compound. This is further illustrated below.

| Diamine/Diisocyanate | Residue |
|---|---|
| 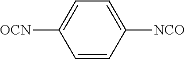 | 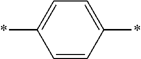 [SMILES: *c1ccc(*)cc1] |
| 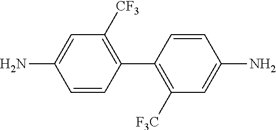 [SMILES: Nc1ccc(-c2ccc(N)cc2C(F)(F)F)c(C(F)(F)F)c1] | 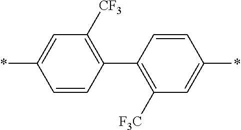 [SMILES: *c1ccc(-c2ccc(*)cc2C(F)(F)F)c(C(F)(F)F)c1] |

The terms “diamine residue” and “diisocyanate residue” are intended to mean the moiety bonded to two amino groups or two isocyanate groups, respectively, where the moiety can be aromatic or aliphatic.

The term “b*” is intended to mean the b* axis in the CIELab Color Space that represents the yellow/blue opponent colors. Yellow is represented by positive b* values, and blue is represented by negative b* values. Measured b* values may be affected by solvent, particularly since solvent choice may affect color measured on materials exposed to high-temperature processing conditions. This may arise as the result of inherent properties of the solvent and/or properties associated with low levels of impurities contained in various solvents. Particular solvents are often preselected to achieve desired b* values for a particular application.

The term “birefringence” is intended to mean the difference in the refractive index in different directions in a polymer film or coating. This term usually refers to the difference between the x- or y-axis (in-plane) and the z-axis (out-of-plane) refractive indices.

The term “charge transport,” when referring to a layer, material, member, or structure is intended to mean such layer, material, member, or structure facilitates migration of such charge through the thickness of such layer, material, member, or structure with relative efficiency and small loss of charge. Hole transport materials facilitate positive charge; electron transport materials facilitate negative charge. Although light-emitting materials may also have some charge transport properties, the term “charge transport layer, material, member, or structure” is not intended to include a layer, material, member, or structure whose primary function is light emission.

The term “compound” is intended to mean an electrically uncharged substance made up of molecules that further include atoms, wherein the atoms cannot be separated from their corresponding molecules by physical means without breaking chemical bonds. The term is intended to include oligomers and polymers.

The term “linear coefficient of thermal expansion (CTE or α)” is intended to mean the parameter that defines the amount which a material expands or contracts as a function of temperature. It is expressed as the change in length per degree Celsius and is generally expressed in units of μm/m/° C.or ppm/° C.

$$α = ( Δ L / {L}_{0} ) / ΔT$$

Measured CTE values disclosed herein are made via known methods during the first or second heating scan. The understanding of the relative expansion/contraction characteristics of materials can be an important consideration in the fabrication and/or reliability of electronic devices.

The term “dopant” is intended to mean a material, within a layer including a host material, that changes the electronic characteristic(s) or the targeted wavelength(s) of radiation emission, reception, or filtering of the layer compared to the electronic characteristic(s) or the wavelength(s) of radiation emission, reception, or filtering of the layer in the absence of such material.

The term “electroactive” as it refers to a layer or a material, is intended to indicate a layer or material which electronically facilitates the operation of the device. Examples of electroactive materials include, but are not limited to, materials which conduct, inject, transport, or block a charge, where the charge can be either an electron or a hole, or materials which emit radiation or exhibit a change in concentration of electron-hole pairs when receiving radiation. Examples of inactive materials include, but are not limited to, planarization materials, insulating materials, and environmental barrier materials.

The term “tensile elongation” or “tensile strain” is intended to mean the percentage increase in length that occurs in a material before it breaks under an applied tensile stress. It can be measured, for example, by ASTM Method D882.

The prefix “fluoro” is intended to indicate that one or more hydrogens in a group have been replaced with fluorine.

The term “glass transition temperature (or Tg)” is intended to mean the temperature at which a reversible change occurs in an amorphous polymer or in amorphous regions of a semi crystalline polymer where the material changes suddenly from a hard, glassy, or brittle state to one that is flexible or elastomeric. Microscopically, the glass transition occurs when normally-coiled, motionless polymer chains become free to rotate and can move past each other. Tg's may be measured using differential scanning calorimetry (DSC), thermo-mechanical analysis (TMA), or dynamic-mechanical analysis (DMA), or other methods.

The prefix “hetero” indicates that one or more carbon atoms have been replaced with a different atom. In some embodiments, the heteroatom is O, N, S, or combinations thereof.

The term “high-boiling” is intended to indicate a boiling point greater than 130° C.

The term “host material” is intended to mean a material to which a dopant is added. The host material may or may not have electronic characteristic(s) or the ability to emit, receive, or filter radiation. In some embodiments, the host material is present in higher concentration.

The term “isothermal weight loss” is intended to mean a material's property that is directly related to its thermal stability. It is generally measured at a constant temperature of interest via thermogravimetric analysis (TGA). Materials that have high thermal stability generally exhibit very low percentages of isothermal weight loss at the required use or processing temperature for the desired period of time and can therefore be used in applications at these temperatures without significant loss of strength, outgassing, and/or change in structure.

The term “liquid composition” is intended to mean a liquid medium in which a material is dissolved to form a solution, a liquid medium in which a material is dispersed to form a dispersion, or a liquid medium in which a material is suspended to form a suspension or an emulsion.

The term “matrix” is intended to mean a foundation on which one or more layers is deposited in the formation of, for example, an electronic device. Non-limiting examples include glass, silicon, and others.

The term “1% TGA Weight Loss” is intended to mean the temperature at which 1% of the original polymer weight is lost due to decomposition (excluding absorbed water).

The term “optical retardation (or RTH)” is intended to mean the difference between the average in-plane refractive index and the out-of-plane refractive index (i.e., the birefringence), this difference then being multiplied by the thickness of the film or coating. Optical retardation is typically measured for a given frequency of light, and the units are reported in nanometers.

The term “organic electronic device” or sometimes “electronic device” is herein intended to mean a device including one or more organic semiconductor layers or materials.

The term “particle content” is intended to mean the number or count of insoluble particles that is present in a solution. Measurements of particle content can be made on the solutions themselves or on finished materials (pieces, films, etc.) prepared from those films. A variety of optical methods can be used to assess this property.

The term “photoactive” refers to a material or layer that emits light when activated by an applied voltage (such as in a light emitting diode or chemical cell), that emits light after the absorption of photons (such as in down-converting phosphor devices), or that responds to radiant energy and generates a signal with or without an applied bias voltage (such as in a photodetector or a photovoltaic cell).

The term “plasma enhanced chemical vapor deposition,” or “PECVD,” refers to a process by which thin films of various materials can be deposited on substrates at lower temperature than are used in standard Chemical Vapor Deposition (CVD) processes.

The term “polyamic acid solution” refers to a solution of a polymer containing amic acid units that have the capability of intramolecular cyclization to form imide groups.

The term “polyimide” refers to condensation polymers resulting from the reaction of one or more bifunctional carboxylic acid components with one or more primary diamines or diisocyanates. They contain the imide structure —CO—NR—CO— as a linear or heterocyclic unit along the main chain of the polymer backbone.

The term “satisfactory,” when regarding a materials property or characteristic, is intended to mean that the property or characteristic fulfills all requirements/demands for the material in-use. For example, an isothermal weight loss of less than 1% at 350° C.for 3 hours in nitrogen can be viewed as a non-limiting example of a “satisfactory” property in the context of the polyimide films disclosed herein.

The term “soft-baking” is intended to mean a process commonly used in electronics manufacture wherein coated materials are heated to drive off solvents and solidify a film. Soft-baking is commonly performed on a hot plate or in exhausted oven at temperatures between 90° C.and 110° C. as a preparation step for subsequent thermal treatment of coated layers or films.

The term “substrate” refers to a base material that can be either rigid or flexible and may include one or more layers of one or more materials, which can include, but are not limited to, glass, polymer, metal or ceramic materials or combinations thereof. The substrate may or may not include electronic components, circuits, or conductive members.

The term “siloxane” refers to the group R₃SiOR₂Si—, where R is the same or different at each occurrence and is H, C1-20 alkyl, fluoroalkyl, or aryl. In some embodiments, one or more carbons in an R alkyl group are replaced with Si.

The term “siloxy” refers to the group R₃SiO—, where R is the same or different at each occurrence and is H, C1-20 alkyl, fluoroalkyl, or aryl.

The term “silyl” refers to the group R₃Si—, where R is the same or different at each occurrence and is H, C1-20 alkyl, fluoroalkyl, or aryl. In some embodiments, one or more carbons in an R alkyl group are replaced with Si.

The term “spin coating” is intended to mean a process used to deposit uniform thin films onto flat substrates. Generally, a small amount of coating material is applied on the center of the substrate, which is either spinning at low speed or not spinning at all. The substrate is then rotated at specified speeds in order to spread the coating material uniformly by centrifugal force.

The term “laser particle counter test” refers to a method used to assess the particle content of polyamic acid and other polymeric solutions whereby a representative sample of a test solution is spin coated onto a 5″ silicon wafer and soft baked/dried. The film thus prepared is evaluated for particle content by any number of standard measurement techniques. Such techniques include laser particle detection and others known in the art.

The term “tensile modulus” is intended to mean the measure of the stiffness of a solid material that defines the initial relationship between the stress (force per unit area) and the strain (proportional deformation) in a material like a film. Commonly used units are giga pascals (GPa).

The term “tetracarboxylic acid component” is intended to mean any one or more of the following: a tetracarboxylic acid, a tetracarboxylic acid monoanhydride, a tetracarboxylic acid dianhydride, a tetracarboxylic acid monoester, and a tetracarboxylic acid diester.

The term “tetracarboxylic acid component residue” is intended to mean the moiety bonded to the four carboxy groups in a tetracarboxylic acid component. This is further illustrated below.

| Tetracarboxylic acid component | Residue |
|---|---|
| 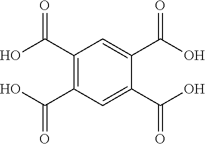 [SMILES: O=C(O)c1cc(C(=O)O)c(C(=O)O)cc1C(=O)O] | 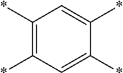 [SMILES: *c1cc(*)c(*)cc1*] |
| 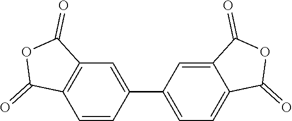 [SMILES: O=C1OC(=O)c2cc(-c3ccc4c(c3)C(=O)OC4=O)ccc21] | 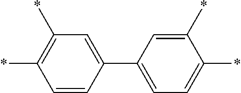 [SMILES: *c1ccc(-c2ccc(*)c(*)c2)cc1*] |
| 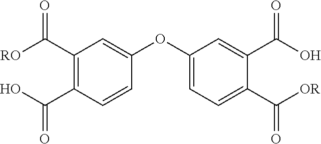 | 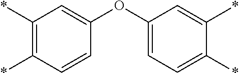 [SMILES: *c1ccc(Oc2ccc(*)c(*)c2)cc1*] |

The term “transmittance” refers to the percentage of light of a given wavelength impinging on a film that passes through the film so as to be detectable on the other side. Light transmittance measurements in the visible region (380 nm to 800 nm) are particularly useful for characterizing film-color characteristics that are most important for understanding the properties-in-use of the polyimide films disclosed herein.

The term “yellowness index (or YI)” refers to the magnitude of yellowness relative to a standard. A positive value of YI indicates the presence, and magnitude, of a yellow color. Materials with a negative YI appear bluish. It should also be noted, particularly for polymerization and/or curing processes run at high temperatures, that YI can be solvent dependent. The magnitude of color introduced using DMAC as a solvent, for example, may be different than that introduced using NMP as a solvent. This may arise as the result of inherent properties of the solvent and/or properties associated with low levels of impurities contained in various solvents. Particular solvents are often preselected to achieve desired YI values for a particular application.

In a structure where a substituent bond passes through one or more rings as shown below,

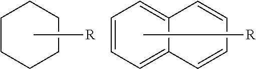

it is meant that the substituent R may be bonded at any available position on the one or more rings.

The phrase “adjacent to,” when used to refer to layers in a device, does not necessarily mean that one layer is immediately next to another layer. On the other hand, the phrase “adjacent R groups,” is used to refer to R groups that are next to each other in a chemical formula (i.e., R groups that are on atoms joined by a bond). Exemplary adjacent R groups are shown below:

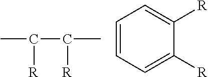

In this specification, unless explicitly stated otherwise or indicated to the contrary by the context of usage, where an embodiment of the subject matter hereof is stated or described as comprising, including, containing, having, being composed of or being constituted by or of certain features or elements, one or more features or elements in addition to those explicitly stated or described may be present in the embodiment. An alternative embodiment of the disclosed subject matter hereof, is described as consisting essentially of certain features or elements, in which embodiment features or elements that would materially alter the principle of operation or the distinguishing characteristics of the embodiment are not present therein. A further alternative embodiment of the described subject matter hereof is described as consisting of certain features or elements, in which embodiment, or in insubstantial variations thereof, only the features or elements specifically stated or described are present.

Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of “a” or “an” are employed to describe elements and components described herein. This is done merely for convenience and to give a general sense of the scope of the invention. This description should be read to include one or at least one and the singular also includes the plural unless it is obvious that it is meant otherwise.

Group numbers corresponding to columns within the Periodic Table of the elements use the “New Notation” convention as seen in the CRC Handbook of Chemistry and Physics, 81^{st} Edition (2000-2001).

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. All publications, patent applications, patents, and other references mentioned herein are incorporated by reference in their entirety, unless a particular passage is cited. In case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, photodetector, photovoltaic, and semiconductive member arts.

### 2. Liquid Composition

There is provided a liquid composition containing (a) a polyamic acid having a repeat unit structure of Formula I

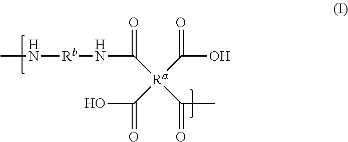

wherein R^{a} is the same or different at each occurrence and represents one or more tetracarboxylic acid component residues and R^{b} is the same or different at each occurrence and represents one or more diamine component residues; (b) one or more phosphorous-containing additives; and (c) a high-boiling aprotic solvent. The liquid composition is also referred to herein as the “polyamic acid solution”.

Examples of suitable phosphorous-containing additives are not particularly limited and are generally selected from the group consisting organophosphorous compounds of P(III), P(V), and derivatives thereof. Non-limiting examples of organophosphorus compounds of P(III) include phosphines (PR₃, including alkyldiaryl phosphines, bidentate alkyldiaryl-phosphines, bidentate triarylphosphines, dialkylarylphosphines, trialkylphosphines, triarylphosphines), aminophosphines (PR₂(NR₂)), phosphinites (PR₂(OR)), diaminophosphines (PR(NR₂)₂), phosphonamidites (PR(OR)(NR₂), phosphonites (PR(OR)₂, including dialkylaryl phosphonites and bidentate aryl phosphonites), triamino-phosphines (P(NR₂)₃), phosphoro-diamidites (P(OR)(NR₂)₂), phosphoramidites (P(OR)₂(NR₂), and phosphites (P(OR)₃, including triaryl phosphites and bidentate aryl phosphites). Generally, in these P(III) compounds R is the same or different at each occurrence and selected from the group consisting of hydrogen, a substituted or unsubstituted (C1-C30)alkyl, a substituted or unsubstituted (C2-C30)alkenyl, a substituted or unsubstituted (C5-C30)aryl, a substituted or unsubstituted 5- to 30-membered heteroaryl, or CN; or may be linked to an adjacent substituent to form a substituted or unsubstituted mono- or polycyclic, (C5-C30) alicyclic or aromatic ring, whose carbon atom(s) may be replaced with at least one heteroatom selected from nitrogen, oxygen, sulfur, Si, PO, SO, SO₂, and SeO₂.

In some non-limiting embodiments of organophosphorus compounds of P(III) at least one of R is a C1-C30 alkyl, in some embodiments all R′s are C1-C30 alkyl.

Non-limiting examples of organophosphorus compounds of P(V) include phosphine oxides (PR₃(O), including trialkyl phosphine oxides and triaryl phosphine oxides), phosphinates (PR₂(O)(OR), including aryl phosphinic acids and dialkyl phosphinic acids), phosphinamides (PR₂(O)(NR₂)), phosphonates (PR(O)(OR)₂, including trialkyl phosphonates, triaryl phosphonates, and dialkylaryl phosphonates), phosphonamidates (PR(O)(OR)(NR₂)), phosphonamides (PR(O)(NR₂)₂), phosphates (P(O)(OR)₃, including alkyl phosphoric acids), phosphor-amidates (P(O)(OR)₂(NR₂)), phosphorodiamidates (P(O)(OR)(NR₂)₂), and phosphoramides (P(O)(NR₂)₃). Generally, in these P(V) compounds R is the same or different at each occurrence and selected from the group consisting of hydrogen, a substituted or unsubstituted (C1-C30)alkyl, a substituted or unsubstituted (C2-C30)alkenyl, a substituted or unsubstituted (C5-C30)aryl, a substituted or unsubstituted 5- to 30-membered heteroaryl, or CN; or may be linked to an adjacent substituent to form a substituted or unsubstituted mono- or polycyclic, (C5-C30) alicyclic or aromatic ring, whose carbon atom(s) may be replaced with at least one heteroatom selected from nitrogen, oxygen, sulfur, Si, PO, SO, SO₂, and SeO₂.

In some non-limiting embodiments of organophosphorus compounds of P(V) at least one of R is a C1-C30 alkyl, in some embodiments all R′s are C1-C30 alkyl.

Non-limiting examples of phosphorous-containing additives include tributylphosphine, trihexylphosphine, bis(2,4,4-trimethylpentyl)phosphinic acid, bis(2,4,4-trimethylpentyl)dithiophosphinic acid, trihexylphosphine oxide, di-n-hexylphosphinous acid, hexyl dihexylphosphinate, di(2-ethylhexyl)phosphate, 9,10-dihydro-9-oxa-10-phosphaphenanthrene-10-oxide, bis(2,4,4-trimethylpentyl) phosphinic acid, trioctylphosphine, bis[(2-diphenyl phosphino)phenyl]ether, 1,3-bis(diphenylphosphino)propane, 2-dicyclohexylphosphino-2′,6′-dimethoxybiphenyl, triphenylphosphine, rac-2-(di-tert-butylphosphino)-1,1′-binaphthyl, 2-(diphenylphosphino)biphenyl, 2,2′-bis(diphenyl phosphino)biphenyl, 1,2-bis(di-2-pyridylphosphino) ethane, 4,6-bis(diphenyl phosphino)phenoxazine, 9,9-dimethyl-4,5-bis(di-tert-butylphosphino)xanthene, (di-tert-butylphosphino)biphenyl, tri-hexylphosphine, tri-1-napthylenylphosphine, 2-di-tert-butylphosphino-2′-(N,N-dimethylamino)biphenyl, tert-butyl diphenyl phosphine, trioctyl-phosphine oxide, triphenylphosphine oxide, triethylphosphine oxide, 9,10-dihydro-9-oxa-10-phosphaphenanthrene 10-oxide, tris(2,4-di-t-butylphenyl)phosphite, diphenyl phenylphosphonate, (di-tert-butylphosphino) biphenyl, tetrakis(2,4-di-tert-butylphenyl) [1,1′-biphenyl]-4,4′-diylbis(phosphonite), trioctylphosphine oxide, (2R,2′R,5R,5′R)-1,1′-(1,2-Ethanediyl)bis[2,5-diphenylphospholane], bis[(2-diphenyl phosphino) phenyl]ether, 4,6-Bis(diphenyl phosphino)dibenzofuran, Diphenyl-4-pyrenylphosphine, 2,2′-Bis(diphenylphosphino) benzophenone, 4,5-bis(diphenylphosphino)-9,9-dimethylxanthene, tris(2,4-di-t-butylphenyl) phosphite, dioctyl phenyl-phosphonate, diethyl 1-octylphosphonate, and tetrakis(2,4-di-tert-butylphenyl) [1, 1′-biphenyl]-4,4′-diylbis (phosphonite).

In some embodiments of the liquid composition disclosed herein, the one or more phosphorous-containing additives is present in the liquid composition at a concentration between 0.01 wt % and 10 wt %, in some non-limiting embodiments between 0.01 wt % and 5 wt %, 0.01 wt % and 2 wt %, in some non-limiting embodiments between 0.025 wt % and 1.5 wt %, in some non-limiting embodiments between 0.05 wt % and 1.0 wt %, in some non-limiting embodiments between 0.1 wt % and 0.75 wt %, in some non-limiting embodiments between 0.15 wt % and 0.4 wt %, and in some non-limiting embodiments between 0.2 wt % and 0.3 wt %.

In some embodiments of Formula I; R^{a} represents a single tetracarboxylic acid component residue, in some embodiments two tetracarboxylic acid component residues, in some embodiments three tetracarboxylic acid residues, in some embodiments four tetracarboxylic acid residues, and in some embodiments five or more tetracarboxylic acid dianhydride residues.

Examples of suitable tetracarboxylic acid dianhydrides include, but are not limited to, pyromellitic dianhydride (PMDA), 3,3′,4,4′-biphenyl tetracarboxylic dianhydride (BPDA), 4,4′-oxydiphthalic anhydride (ODPA), 3,3′,4,4′-benzophenone tetracarboxylic dianhydride (BTDA), 3,3′,4,4′-diphenylsulfone tetracarboxylic dianhydride (DSDA), 4,4′-bisphenol-A dianhydride (BPADA), hydroquinone diphthalic anhydride (HQDEA), ethylene glycol bis (trimellitic anhydride) (TMEG-100), 4-(2,5-dioxotetrahydrofuran-3-yl)-1,2,3,4-tetrahydronapthalene-1,2-dicarboyxlic anhydride (DTDA); 4,4′-bisphenol A dianhydride (BPADA), cyclobutane dianhydride (CBDA); 9,9-bis(3,4-dicarboxyphenyl)fluorene dianhydrid; 3-(carboxymethyl)-1,2,4-cyclopentanetricarboxylic acid 1,4:2,3-dianhydride; bicyclo[2.2.2]oct-7-ene-2,3,5,6-tetracarboxylic dianhydride; 1,2,3,4-cyclopentanetetracarboxylic dianhydride; 1,2,4,5-cyclohexane-tetracarboxylic dianhydride; 1,2,3,4-tetramethyl-1,2,3,4-cyclobutanetetracarboxylic dianhydride; 1,3-dimethyl-1,2,3,4-cyclobutane-tetracarboxylic acid dianhydride; tricyclo[6.4.0.02,7]dodecane-1,8:2,7-tetracarboxylic dianhydride; meso-butane-1,2,3,4-tetracarboxylic dianhydride; 4-(2,5-dioxotetrahydrofuran-3-yl)-1,2,3,4-tetrahydro-naphthalene-1,2-dicarboxylic anhydride; 5-(2,5-dioxotetrahydrofuryl)-3-methyl-3-cyclohexene-1,2-dicarboxylic anhydride and the like and combinations thereof. These dianhydrides may optionally be substituted with groups that are known in the art including alkyl, aryl, nitro, cyano, —N(R′)(R″), halo, hydroxy, carboxy, alkenyl, alkynyl, cycloalkyl, heteroaryl, alkoxy, aryloxy, heteroaryloxy, alkoxycarbonyl, perfluoroalkyl, perfluoroalkoxy, arylalkyl, silyl, siloxy, siloxane, thioalkoxy, —S(O)₂—, —C(′O)—N(R′)(R″), (R′)(R″)N-alkyl, (R′)(R″)N-alkoxyalkyl, (R′)(R″)N-alkylaryloxyalkyl, S(O)ₛ-aryl (where s=0-2) or —S(O)ₛ-heteroaryl (where s=0-2). Each R′ and R″ is independently an optionally substituted alkyl, cycloalkyl, or aryl group. R′ and R″, together with the nitrogen atom to which they are bound, can form a ring system in certain embodiments. Substituents may also be crosslinking groups. Halo substitution with one or more F atoms per tetracarboxylic acid dianhydride renders fluorinated embodiments of these species.

In some embodiments, the introduction of fluorine atoms into polyimides produces materials and films with properties better-suited to the end uses disclosed herein. The high electronegativity of fluorine atoms results in strong bonds between carbon and fluorine atoms, and can give the associated fluorocarbon materials relatively high thermal and chemical stability. The fluorine atoms may also, in some embodiments, increases the solubility, processability, and transparency and help in decreasing water absorption and dielectric constant of the resultant polyimide.

One strategy for incorporation of fluorine into the liquid compositions and films disclosed herein is to incorporate fluorine into the tetracarboxylic acid component residues. Non-limiting examples of suitable tetracarboxylic acid dianhydrides wherein one or more of the R^{a} includes one or more F atoms per residue include, but are not limited to, 4,4′-hexafluoroiso-propylidenebisphthalic dianhydride (6FDA). 1H-difuro[3,4-b:3′,4′-i ]xanthene1,3,7,9(11 H)-tetrone, 11,11bis(trifluoro-methyl); 1H-difuro[3,4-b:3′,4′-i ]xanthene1,3,7,9(11 H)-tetrone, 11-phenyl-11(trifluoromethyl); 1H ,3 H -benzo[1,2-c :4,5-c′]difuran-1,3,5,7tetrone, 4,8-bis(trifluoromethyl); 1 H , 3H-Benzo[1,2-c:4,5-c′]difuran-1,3,5,7tetrone, 4,8-difluoro; 1H -difuro[3,4-b:3′,4′-i]xanthene-1,3,7,9(11 H)-tetrone, 11-methyl-11(trifluoromethyl). These dianhydrides may optionally be substituted with groups that are known in the art including alkyl, aryl, nitro, cyano, —N(R′)(R″), halo, hydroxy, carboxy, alkenyl, alkynyl, cycloalkyl, heteroaryl, alkoxy, aryloxy, heteroaryloxy, alkoxycarbonyl, perfluoroalkyl, perfluoroalkoxy, arylalkyl, silyl, siloxy, siloxane, thioalkoxy, —S(O)₂—, —C(═O)—N(R′)(R″), (R′)(R″)N-alkyl, (R′)(R″)N-alkoxyalkyl, (R′)(R″)N-alkylaryloxyalkyl, —S(O)ₛ-aryl (where s=0-2) or —S(O)ₛ-heteroaryl (where s=0-2). Each R′ and R″ is independently an optionally substituted alkyl, cycloalkyl, or aryl group. R′ and R″, together with the nitrogen atom to which they are bound, can form a ring system in certain embodiments. Substituents may also be crosslinking groups.

In some embodiments of Formula I, R^{a} represents one or more residues from tetracarboxylic acid dianhydrides selected from the group consisting of PMDA, BPDA, 6FDA, and BTDA. In some embodiments a PMDA residue; in some embodiments a BPDA residue; in some embodiments a 6FDA residue; in some embodiments a BTDA residue; in some embodiments a PMDA residue, a BPDA residue, and a 6FDA residue; in some embodiments a PMDA residue and a 6FDA residue; in some embodiments a BPDA residue and a 6FDA residue; and in some embodiments a BTDA residue and a 6FDA residue.

In some embodiments of Formula I; R^{b} represents a single diamine component residue, in some embodiments two diamine component residues, in some embodiments three diamine component residues, in some embodiments four diamine component residues, and in some embodiments five or more diamine component residues.

Examples of suitable diamines include, but are not limited to, p-phenylene diamine (PPD), 2,2′-dimethyl-4,4′-diaminobiphenyl (m-tolidine), 3,3′-dimethyl-4,4′-diaminobiphenyl (o-tolidine), 3,3′-dihydroxy-4,4′-diaminobiphenyl (HAB), 9,9′-bis(4-aminophenyl)fluorene (FDA), o-tolidine sulfone (TSN), 2,3,5,6-tetramethyl-1,4-phenylenediamine (TMPD), 2,4-diamino-1,3,5-trimethyl benzene (DAM), 2,2-bis[4-(4-aminophenoxy) phenyl]propane (BAPP), 4,4′-methylene dianiline (MDA), 4,4′-[1,3-phenylenebis(1-methyl-ethylidene)]bisaniline (Bis-M), 4,4′-[1,4-phenylenebis(1-methyl-ethylidene)]bisaniline (Bis-P), 4,4′-oxydianiline (4,4′-ODA), m-phenylene diamine (MPD), 3,4′-oxydianiline (3,4′-ODA), 3,3′-diaminodiphenyl sulfone (3,3′-DDS), 4,4′-diaminodiphenyl sulfone (4,4′-DDS), 4,4′-diaminodiphenyl sulfide (ASD), 2,2-bis[4-(4-amino-phenoxy)phenyl]sulfone (BAPS), 2,2-bis[4-(3-aminophenoxy)-phenyl]sulfone (m-BAPS), 1,4′-bis(4-aminophenoxy)benzene (TPE-Q), 1,3′-bis(4-aminophenoxy)benzene (TPE-R), 1,3′-bis(4-amino-phenoxy)benzene (APB-133), 4,4′-bis(4-aminophenoxy)biphenyl (BAPB), 4,4′-diaminobenzanilide (DABA), methylene bis(anthranilic acid) (MBAA), 1,3′-bis(4-aminophenoxy)-2,2-dimethylpropane (DANPG), 1,5-bis(4-aminophenoxy)pentane (DA5MG), 3,3′5,5′-tetramethyl-4,4′-diamino diphenylmethane (TMMDA), and the like and combinations thereof.

These diamines may optionally be substituted with groups that are known in the art including alkyl, aryl, nitro, cyano, —N(R′)(R″), halo, hydroxy, carboxy, alkenyl, alkynyl, cycloalkyl, heteroaryl, alkoxy, aryloxy, heteroaryloxy, alkoxycarbonyl, perfluoroalkyl, perfluoroalkoxy, arylalkyl, silyl, siloxy, siloxane, thioalkoxy, —S(O)₂—, —C(═O)—N(R′)(R″), (R′)(R″)N-alkyl, (R′)(R″)N-alkoxyalkyl, (R′)(R″)N-alkylaryloxyalkyl, —S(O)ₛ-aryl (where s=0-2) or —S(O)ₛ-heteroaryl (where s=0-2). Each R′ and R″ is independently an optionally substituted alkyl, cycloalkyl, or aryl group. R′ and R″, together with the nitrogen atom to which they are bound, can form a ring system in certain embodiments. Substituents may also be crosslinking groups. As discussed above, incorporation of fluorine into the liquid compositions disclosed herein can, in some embodiments, lead to the production of polyimide films with superior thermal, optical, and other properties for the uses disclosed. Halo substitution with one or more F atoms per diamine renders fluorinated embodiments of these species and thus represents one general synthetic strategy for the incorporation of fluorine.

Additional examples of suitable diamines wherein one or more of the R^{b} includes one or more F atoms per residue include, but are not limited to, 2,2′-bis(trifluoromethyl) benzidine (22TFMB or TFMB), 3,3′-Bis (trifluoromethyl) benzidine (33TFMB), 2,2′-bis[4-(4-aminophenoxy pehnyl)]hexafluoropropane (HFBAPP), 2,2-bis(4-aminophenyl) hexafluoropropane (Bis-A-AF), 2,2-bis(3-amino-4-hydroxyphenyl) hexa-fluoropropane (Bis-AP-AF), 2,2-bis(3-amino-4-methylphenyl) hexa-fluoropropane (Bis-AT-AF), 1,4-Bis(2-trifluoromethyl-4 aminophenoxy) benzene (p-6FAPB), 4,4′-bis(4-amino-2-trifluoromethyl phenoxy)biphenyl (6BFBAPB), N,N′-(2,2′-bis(trifluoromethyl)-[1,1′-biphenyl]-4,4′-diyl)bis(4-aminobenzamide) (AB-TFMB), 9,9-bis(4-amino-3-fluorophenyl)fluorene, and the like and combinations thereof. These diamines may optionally be substituted with groups that are known in the art including alkyl, aryl, nitro, cyano, —N(R′)(R″), halo, hydroxy, carboxy, alkenyl, alkynyl, cycloalkyl, heteroaryl, alkoxy, aryloxy, heteroaryloxy, alkoxycarbonyl, perfluoroalkyl, perfluoroalkoxy, arylalkyl, silyl, siloxy, siloxane, thioalkoxy, —S(O)₂—, —C(═O)—N(R′)(R″), (R′)(R″)N-alkyl, (R′)(R″)N-alkoxyalkyl, (R′)(R″)N-alkylaryloxyalkyl, —S(O)ₛ-aryl (where s=0-2) or —S(O)ₛ-heteroaryl (where s=0-2). Each R′ and R″ is independently an optionally substituted alkyl, cycloalkyl, or aryl group. R′ and R″, together with the nitrogen atom to which they are bound, can form a ring system in certain embodiments. Substituents may also be crosslinking groups.

In some embodiments of Formula I, R^{b} represents one or more residues from diamines selected from the group consisting of PPD, MPD, TFMB, and Bis-A-AF. In some embodiments a PPD residue; in some embodiments an MPD residue; in some embodiments a TFMB residue; in some embodiments a Bis-A-AF residue; in some embodiments a PPD residue, an MPD residue, and a TFMB residue; in some embodiments a PPD residue and a TFMB residue; in some embodiments a MPD residue and a TFMB residue; and in some embodiments a Bis-A-AF residue and a TFMB residue.

Additional non-limiting embodiments of suitable tetracarboxylic acid dianhydrides and diamines are those described, for example, in published patent applications US 2020-0140615, WO 2020/033471, WO 2020/219411, US 2020-0216614, US 2020-0172675, WO 2019/246233, US 2021-0017335, WO 2019/222304, WO 2019/246235, WO 2020/018621, WO2020/033475, WO 2020/018617, and WO 2020/033480. The person skilled in the art would recognize that these disclosures describe either dianhydrides, diamines, or both; and in some cases fluorine substitution is present.

Benefits realized from use of the liquid compositions disclosed herein for the production of clear or low-color polyimide films may, in some embodiments, be measurably superior to those that may be realized from more-conventional formulations used to produce amber polyimides. That is, the use of fluorine-containing tetracarboxylic acid component residues and/or diamine component residues as constituents of liquid compositions that also include phosphorous-containing additives may provide surprising and unexpected improvements in thermal, optical, mechanical, and other properties of the associated polyimide films.

In some non-limiting embodiments of the liquid compositions disclosed herein, R^{a} contains one or more F atoms per tetracarboxylic acid component residue. In some non-limiting embodiments of the liquid compositions disclosed herein, R^{b} contains one or more F atoms per tetracarboxylic acid component residue. In some non-limiting embodiments of the liquid compositions disclosed herein, one or more of R^{a} and R^{b} contains one or more F atoms per residue.

The use of fluorine-containing components may not be limiting in this regard, but any strategy known in the art for producing low- or lower-color polyimides may benefit similarly from the inclusion of the phosphorous-containing additives disclosed herein. Non-limiting examples of such strategies include the incorporation of aliphatic moieties, flexible groups, and others known to those having skill in the art. These liquid compositions for clear or low-color polyimide films comprising the phosphorous-containing additives disclosed herein may similarly provide surprising and unexpected improvements in thermal, optical, mechanical, and other properties of the associated polyimide films versus their amber counterparts.

In some non-limiting embodiments of Formula I, moieties resulting from monoanhydride monomers are present as end-capping groups.

In some non-limiting embodiments, the monoanhydride monomers are selected from the group consisting of phthalic anhydrides and the like and derivatives thereof.

In some non-limiting embodiments, the monoanhydrides are present at an amount up to 5 mol % of the total tetracarboxylic acid composition.

In some non-limiting embodiments of Formula I, moieties resulting from monoamine monomers are present as end-capping groups.

In some non-limiting embodiments, the monoamine monomers are selected from the group consisting of aniline and the like and derivatives thereof.

In some non-limiting embodiments, the monoamines are present at an amount up to 5 mol % of the total amine composition.

In some embodiments, the polyamic acid has a weight average molecular weight (Mw) greater than 100,000 based on gel permeation chromatography with polystyrene standards; in some non-limiting embodiments greater than 150,000; in some non-limiting embodiments greater than 200,000; in some non-limiting embodiments greater than 250,000; in some non-limiting embodiments greater than 300,000; in some non-limiting embodiments between 100,000 and 400,000; in some non-limiting embodiments between 200,000 and 400,000; in some non-limiting embodiments between 250,000 and 350,000; and in some non-limiting embodiments between 200,000 and 300,000.

Any of the above embodiments for the polyamic acid can be combined with one or more of the other embodiments, so long as they are not mutually exclusive. For example, the embodiment in which Ra represents a PMDA residue can be combined with the embodiments in which R^{b} represents a TFMB residue.

In some non-limiting embodiments of the liquid composition disclosed herein; the high-boiling aprotic solvent has a boiling point of 150° C. or higher, in some non-limiting embodiments 175° C. or higher, and in some non-limiting embodiments 200° C. or higher.

In some non-limiting embodiments of the liquid composition disclosed herein; the high-boiling aprotic solvent is a polar solvent. In some non-limiting embodiments, the solvent has a dielectric constant greater than 20.

Some non-limiting examples of high-boiling aprotic solvents include, but are not limited to, N-methyl-2-pyrrolidone (NMP), dimethyl acetamide (DMAc), dimethyl sulfoxide (DMSO), dimethyl formamide (DMF), γ-butyrolactone, dibutyl carbitol, butyl carbitol acetate, diethylene glycol monoethyl ether acetate, propylene glycol monomethyl ether acetate and the like, and combinations thereof.

In some non-limiting embodiments of the liquid composition disclosed herein, the solvent is selected from the group consisting of NMP, DMAc, and DMF. In some non-limiting embodiments of the liquid composition disclosed herein; the solvent is NMP, in some non-limiting embodiment DMAc, and in some non-limiting embodiments DMF.

In some non-limiting embodiments of the liquid composition disclosed herein; the solvent is γ-butyrolactone, in some non-limiting embodiments dibutyl carbitol, in some non-limiting embodiments butyl carbitol acetate, in some non-limiting embodiments diethylene glycol monoethyl ether acetate, and in some non-limiting embodiments propylene glycol monoethyl ether acetate.

In some embodiments, more than one of the high-boiling aprotic solvents identified above is used in the liquid composition.

In some embodiments, additional cosolvents are used in the liquid composition.

The polyamic acid solutions can optionally further contain any one of a number of additives. Such additives can be: antioxidants, heat stabilizers, adhesion promoters, coupling agents (e.g. silanes), inorganic fillers or various reinforcing agents so long as they don't adversely impact the desired polyimide properties.

In some non-limiting embodiments of the liquid composition disclosed herein; the solids content is at least 10 wt %, in some non-limiting embodiments at least 12 wt %, in some non-limiting embodiments at least 15 wt %. In some non-limiting embodiments, the solids content is 10-20 wt %.

In some non-limiting embodiments of the liquid composition disclosed herein; the viscosity is at least about 3000 cps, in some non-limiting embodiments at least about 5,000 cps, and in some non-limiting embodiments at least about 10,000 cps.

The liquid compositions comprising polyamic acid solutions disclosed herein can be prepared using a variety of available methods with respect to the introduction of the components (i.e., the monomers, additives, and solvents). Some methods of producing the liquid composition comprising a polyamic acid solution include:
(a) a method wherein the diamine components and dianhydride components are preliminarily mixed together and then the mixture is added in portions to a solvent while stirring.
(b) a method wherein a solvent is added to a stirring mixture of diamine and dianhydride components. (contrary to (a) above)
(c) a method wherein diamines are exclusively dissolved in a solvent and then dianhydrides are added thereto at such a ratio as allowing to control the reaction rate.
(d) a method wherein the dianhydride components are exclusively dissolved in a solvent and then amine components are added thereto at such a ratio to allow control of the reaction rate.
(e) a method wherein the diamine components and the dianhydride components are separately dissolved in solvents and then these solutions are mixed in a reactor.
(f) a method wherein the polyamic acid with excessive amine component and another polyamic acid with excessive dianhydride component are preliminarily formed and then reacted with each other in a reactor, particularly in such a way as to create a non-random or block copolymer.
(g) a method wherein a specific portion of the amine components and the dianhydride components are first reacted and then the residual diamine components are reacted, or vice versa.
(h) a method wherein the components are added in part or in whole in any order to either part or whole of the solvent, also where part or all of any component can be added as a solution in part or all of the solvent.
(i) a method of first reacting one of the dianhydride components with one of the diamine components giving a first polyamic acid. Then reacting the other dianhydride component with the other amine component to give a second polyamic acid. Then combining the polyamic acids in any one of a number of ways prior to film formation.

The one or more phosphorous-containing additives may be added to the polyamic acid solutions either before or after polymerization steps as initiated above. In some non-limiting embodiments, a polyamic acid solution composition comprising one or more phosphorous-containing additives may be obtained by first introducing the phosphorous-containing additive into a solvent and agitating it for a pre-selected time interval which may be in excess of 2 hours, in some non-limiting embodiment in excess of 4 hours, in some non-limiting embodiments in excess of 8 hours, in some non-limiting embodiments in excess of 10 hours, in some non-limiting embodiments in excess of 15 hours, in some non-limiting embodiments in excess of 20 hours, in some non-limiting embodiments in excess of 25 hours, and in some non-limiting embodiments in excess of 30 hours. The one or more tetracarboxylic acid components and one or more diamine components as disclosed herein are then introduced into the solvent/additive mixture in this “pre-treatment” protocol.

In other non-limiting embodiments, a polyamic acid solution composition comprising one or more phosphorous-containing additives may be obtained by first adding one or more tetracarboxylic acid components and one or more diamine components to the selected solvent, allowing the formation of the polyamic acid solution, and finally introducing the one or more phosphorous-containing additives. This can be referred to as “post-treatment.”

Generally speaking, liquid composition comprising a polyamic acid can be obtained from any one of the polyamic acid solution preparation methods disclosed above.

The liquid composition can then optionally be filtered one or more times in order to reduce the particle content. The polyimide film generated from such a filtered solution can show a reduced number of defects and thereby lead to superior performance in the electronics applications disclosed herein. An assessment of the filtration efficiency can be made by the laser particle counter test wherein a representative sample of the polyamic acid solution is cast onto a 5″ silicon wafer. After soft baking/drying, the film is evaluated for particle content by any number of laser particle counting techniques on instruments that are commercially available and known in the art.

In some non-limiting embodiments; the liquid composition is prepared and filtered to yield a particle content of less than 40 particles as measured by the laser particle counter test, in some non-limiting embodiments less than 30 particles, in some non-limiting embodiments less than 20 particles, in some non-limiting embodiments less than 10 particles, in some non-limiting embodiments between 2 particles and 8 particles, and in some non-limiting embodiments between 4 particles and 6 particles as measured by the laser particle counter test.

Exemplary preparations of liquid compositions comprising polyamic acid solutions are given in the examples.

Overall polyamic acid compositions can be designated via the notation commonly used in the art. For example, a polyamic acid having a tetracarboxylic acid component that is 100% ODPA, and a diamine component that is 90 mol % Bis-P and 10 mol % TFMB, would be represented as:
ODPA//Bis-P/TFMB 100//90/10.

### 3. Polyimide Film

There is provided a polyimide film made from the above-described liquid composition.

The polyimide has a repeat unit structure of Formula II

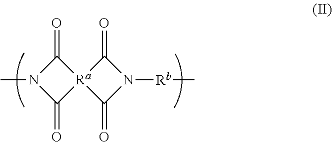

wherein R^{a} is the same or different at each occurrence and represents one or more tetracarboxylic acid component residues and R^{b} is the same or different at each occurrence and represents one or more diamine residues; and further wherein the polyimide film is prepared according to a method comprising the following steps in order and without repeating: coating a polyamic acid solution comprising one or more tetracarboxylic acid components and one or more diamine components in a high-boiling, aprotic solvent onto a matrix; soft-baking the coated matrix; treating the soft-baked coated matrix at a plurality of pre-selected temperatures for a plurality of pre-selected time intervals.

All of the above-described embodiments for R^{a} and R^{b} in Formula I apply equally to R^{a} and R^{b} in Formula Il.

The polyimide films are made by coating the above-described liquid composition onto a substrate and subsequently imidizing. This can be accomplished by a thermal conversion process or a chemical conversion process. Any known coating method can be used.

Some fluorinated diamines are known to have low reactivity. In order to form polyimide films with sufficient molecular weight with these low reactivity diamines, multiple polymerization steps are used. Typically, a polyamic acid solution is prepared with the low reactivity diamine, the solution is coated and imidized, the imidized product dissolved, recoated and reimidized. The additional dissolving, recoating and reimidizing steps are repeated several times.

In some non-limiting embodiments of the polyimide film; the polyimide polymer has a weight average molecular weight (Mw) greater than 100,000 based on gel permeation chromatography with polystyrene standards, in some non-limiting embodiments greater than 150,000, in some non-limiting embodiments greater than 200,000, in some non-limiting embodiments greater than 250,000, in some non-limiting embodiments greater than 300,000, in some non-limiting between 100,000 and 400,000, in some non-limiting between 200,000 and 400,000, in some non-limiting embodiments between 250,000 and 350,000, and in some non-limiting embodiments between 200,000 and 300,000.

In some non-limiting embodiments of the polyimide film; the in-plane coefficient of thermal expansion (CTE) is less than 45 ppm/° C. between 50° C. and 250° C.; in some non-limiting embodiments, less than 30 ppm/° C.; in some non-limiting embodiments, less than 20 ppm/° C.; in some non-limiting embodiments, less than 15 ppm/° C.; in some non-limiting embodiments, between 0 ppm/° C. and 15 ppm/° C.; in some non-limiting embodiments, between 0 ppm/° C. and 10 ppm/° C, and in some non-limiting embodiments between 4 ppm/° C. and 7 ppm/° C.

In some non-limiting embodiments of the polyimide film; the in-plane coefficient of thermal expansion (CTE) is less than 45 ppm/° C. between 50° C.and 300° C.; in some non-limiting embodiments, less than 30 ppm/° C.; in some non-limiting embodiments, less than 20 ppm/° C.; in some non-limiting embodiments, less than 15 ppm/° C.; in some non-limiting embodiments, between 0 ppm/° C. and 15 ppm/° C.; in some non-limiting embodiments, between 0 ppm/° C. and 10 ppm/° C., and in some non-limiting embodiments between 4 ppm/° C. and 8 ppm/° C.

In some non-limiting embodiments of the polyimide film; the in-plane coefficient of thermal expansion (CTE) is less than 45 ppm/° ° C. between 50° C. and 350° C.; in some non-limiting embodiments, less than 30 ppm/° C.; in some non-limiting embodiments, less than 20 ppm/° C.; in some non-limiting embodiments, less than 15 ppm/° C.; in some non-limiting embodiments, between 0 ppm/° C. and 15 ppm/° C.; in some non-limiting embodiments, between 0 ppm/° C. and 10 ppm/° C, and in some non-limiting embodiments between 3 ppm/° C. and 9 ppm/° C. In some non-limiting embodiments of the polyimide film; the in-plane coefficient of thermal expansion (CTE) is less than 45 ppm/° C between 50° C. and 400° C.; in some non-limiting embodiments, less than 30 ppm/° C.; in some non-limiting embodiments, less than 20 ppm/° C.; in some non-limiting embodiments, less than 15 ppm/° C.; in some non-limiting embodiments, between 0 ppm/° C. and 15 ppm/° C.; in some non-limiting embodiments, and in some non-limiting embodiments between 6 ppm/° C. and 12 ppm/° C.

In some non-limiting embodiments of the polyimide film; the in-plane coefficient of thermal expansion (CTE) is less than 45 ppm/° C. between 50° C.and 450° C.; in some non-limiting embodiments, less than 30 ppm/° C.; in some non-limiting embodiments, less than 20 ppm/° C.; in some non-limiting embodiments, less than 15 ppm/° C.; in some non-limiting embodiments, between 0 ppm/° C. and 15 ppm/° C.; in some non-limiting embodiments, and in some non-limiting embodiments between 8 ppm/° C. and 14 ppm/° C.

In some non-limiting embodiments of the polyimide film, the glass transition temperature (Tg) is greater than 250° C.for a polyimide film cured at a temperature above 300° C.; in some non-limiting embodiments, greater than 300° C.; in some non-limiting embodiments, greater than 350 ° C.

In some non-limiting embodiments of the polyimide film, the glass transition temperature (Tg) is greater than 400° C.for a polyimide film cured at a temperature above 375° C.; in some non-limiting embodiments, greater than 410° C.; in some non-limiting embodiments, greater than 450° C.

In some non-limiting embodiments of the polyimide film, the glass transition temperature (Tg) is greater than 430° C.for a polyimide film cured at a temperature above 400° C.; in some non-limiting embodiments, greater than 450° C.; in some non-limiting embodiments, greater than 480° C.

In some non-limiting embodiments of the polyimide film; the 0.5% TGA weight loss temperature is greater than 350° C., in some non-limiting embodiments embodiments greater than 400° C., in some non-limiting embodiments greater than 450° C., in some non-limiting embodiments greater than 500° C., and in some non-limiting embodiments greater than 550° ° C.

In some non-limiting embodiments of the polyimide film; the 1% TGA weight loss temperature is greater than 350° C., in some non-limiting embodiments embodiments greater than 400° C., in some non-limiting embodiments greater than 450° C., in some non-limiting embodiments greater than 500° C., and in some non-limiting embodiments greater than 550° C.

In some non-limiting embodiments of the polyimide film; the tensile modulus is between 1.5 GPa and 15.0 GPa, in some non-limiting embodiments between 1.5 GPa and 12.0 GPa, and in some non-limiting embodiments between 3 GPa and 8 GPa.

In some non-limiting embodiments of the polyimide film; the tensile strength is between 100 MPa and 250 MPa, in some non-limiting embodiments between 150 MPa and 225 MPa, and in some non-limiting embodiments between 175 MPa and 200 MPa.

In some non-limiting embodiments of the polyimide film; the elongation to break is greater than 10%, in some non-limiting embodiments greater than 15%, in some non-limiting embodiments greater than 20%, and in some non-limiting embodiments greater than 25%.

In some non-limiting embodiments of the polyimide film; the optical retardation is less than 500 at 550 nm, in some non-limiting embodiments less than 200, and in some non-limiting embodiments less than 150.

In some non-limiting embodiments of the polyimide film; the birefringence at 633 nm is less than 0.15, in some embodiments less than 0.10, and in some non-limiting embodiments less than 0.05.

In some non-limiting embodiments of the polyimide film; the haze is less than 1.0%, in some non-limiting embodiments less than 0.5%, and in some non-limiting embodiments less than 0.25%.

In some non-limiting embodiments of the polyimide film; the b* is less than 10, in some non-limiting embodiments less than 7.5, in some non-limiting embodiments less than 5, and in some non-limiting embodiments less than 3. In some non-limiting embodiments of the polyimide film the YI is less than 20, in some non-limiting embodiments less than 15, in some non-limiting embodiments less than 10, and in some non-limiting embodiments less than 5.

In some non-limiting embodiments of the polyimide film; the transmittance at 400 nm is greater than 40%, in some non-limiting embodiments, greater than 50%, and in some non-limiting embodiments, greater than 60%.

In some non-limiting embodiments of the polyimide film; the transmittance at 430 nm is greater than 60%, and in some non-limiting embodiments greater than 70%.

In some non-limiting embodiments of the polyimide film; the transmittance at 450 nm is greater than 70%, and in some non-limiting embodiments greater than 80%.

In some non-limiting embodiments of the polyimide film; the transmittance at 550 nm is greater than 70%, and in some non-limiting embodiments greater than 80%.

In some non-limiting embodiments of the polyimide film; the transmittance at 750 nm is greater than 70%, in some non-limiting embodiments greater than 80%, and in some non-limiting embodiments, greater than 90%.

In some non-limiting embodiments of the polyimide film; the average transmittance between 380 nm and 780 nm is greater than 70%, in some non-limiting embodiments greater than 80%, and in some non-limiting embodiments, greater than 90%.

Any of the above embodiments for the polyimide film can be combined with one or more of the other embodiments, so long as they are not mutually exclusive.

The polyimide films are prepared from the polyamic acid solutions by chemical or thermal conversion processes. The polyimide films disclosed herein, particularly when used as flexible replacements for glass in electronic devices, are prepared by thermal conversion or modified-thermal conversion processes, versus chemical conversion processes.

Chemical conversion processes are described in U.S. Pat. Nos. 5,166,308 and 5,298,331 which are incorporated by reference in their entirety. In such processes, conversion chemicals are added to the polyamic acid solutions. The conversion chemicals found to be useful in the present invention include, but are not limited to, (i) one or more dehydrating agents, such as, aliphatic acid anhydrides (acetic anhydride, etc.) and acid anhydrides; and (ii) one or more catalysts, such as, aliphatic tertiary amines (triethylamine, etc.), tertiary amines (dimethylaniline, etc.) and heterocyclic tertiary amines (pyridine, picoline, isoquinoilne, etc.). The anhydride dehydrating material is typically used in a slight molar excess of the amount of amide acid groups present in the polyamic acid solution. The amount of acetic anhydride used is typically about 2.0-3.0 moles per equivalent of the polyamic acid. Generally, a comparable amount of tertiary amine catalyst is used.

Thermal conversion processes may or may not employ conversion chemicals (i.e., catalysts) to convert a polyamic acid casting solution to a polyimide. If conversion chemicals are used, the process may be considered a modified-thermal conversion process. In both types of thermal conversion processes, only heat energy is used to heat the film to both dry the film of solvent and to perform the imidization reaction. Thermal conversion processes with or without conversion catalysts are generally used to prepare the polyimide films disclosed herein.

Specific method parameters are pre-selected considering that it is not just the film composition that yields the properties of interest. Rather, the cure temperature and temperature-ramp profile also play important roles in the achievement of the most desirable properties for the intended uses disclosed herein. The polyamic acids should be imidized at a temperature at, or higher than, the highest temperature of any subsequent processing steps (e.g. deposition of inorganic or other layer(s) necessary to produce a functioning display), but at a temperature which is lower than the temperature at which significant thermal degradation/discoloration of the polyimide occurs. It should also be noted that an inert atmosphere is generally preferred, particularly when higher processing temperatures are employed for imidization.

For the polyamic acids/polyimides disclosed herein, temperatures of 300° ° C.to 320° C.are typically employed when subsequent processing temperatures in excess of 300° C. are required. In some non-limiting embodiments wherein subsequent processing temperatures are higher;

temperatures in excess of 320° C.are employed, in some non-limiting embodiments temperatures in excess of 350° C., in come non-limiting embodiments temperatures in excess of 400° C., and in some non-limiting embodiments temperatures in excess of 450° C. Choosing the proper curing temperature allows a fully cured polyimide which achieves the best balance of thermal and mechanical properties. Because of this very high temperature, an inert atmosphere is required. Typically, oxygen levels in the oven of <100 ppm should be employed. Very low oxygen levels enable the highest curing temperatures to be used without significant degradation/discoloration of the polymer. Catalysts that accelerate the imidization process are effective at achieving higher levels of imidization at cure temperatures between about 200° C. and 300° C. This approach may be optionally employed if the flexible device is prepared with upper cure temperatures that are below the Tg of the polyimide.

The amount of time in each potential cure step is also an important process consideration. Generally, the time used for the highest-temperature curing should be kept to a minimum. For 320° C.cure, for example, cure time can be up to an hour or so under an inert atmosphere; but at higher cure temperatures, this time should be shortened to avoid thermal degradation. Generally speaking, higher temperature dictates shorter time. Those skilled in the art will recognize the balance between temperature and time in order to optimize the properties of the polyimide for a particular end use.

In some non-limiting embodiments, the liquid composition is converted into a polyimide film via a thermal conversion process.

In some non-limiting embodiments of the thermal conversion process; the polyamic acid solution is coated onto the matrix such that the soft-baked thickness of the resulting film is less than 50 μm, in some non-limiting embodiments less than 40 μm, in some non-limiting embodiments less than 30 μm, in some non-limiting embodiments less than 20 μm, in some non-limiting embodiments between 10 μm and 20 μm, in some non-limiting embodiments between 15 μm and 20 μm, and in some non-limiting embodiments 18 μm. In some non-limiting embodiments of the thermal conversion process; the polyamic acid solution is coated onto the matrix such that the soft-baked thickness of the resulting film is less than 10 μm.

In some non-limiting embodiments of the thermal conversion process; the coated matrix is soft baked on a hot plate in proximity mode wherein nitrogen gas is used to hold the coated matrix just above the hot plate. In some non-limiting embodiments of the thermal conversion process; the coated matrix is soft baked on a hot plate in full-contact mode wherein the coated matrix is in direct contact with the hot plate surface. In some non-limiting embodiments of the thermal conversion process, the coated matrix is soft baked on a hot plate using a combination of proximity and full-contact modes.

In some non-limiting embodiments of the thermal conversion process; the coated matrix is soft-baked using a hot plate set at 80° C., in some non-limiting embodiments 90° C., in some non-limiting embodiments 100° C., in some non-limiting embodiments 110° C., in some non-limiting embodiments 120° C., in some non-limiting embodiments 130° C., and in some non-limiting embodiments 140° C.

In some non-limiting embodiments of the thermal conversion process; the coated matrix is soft-baked for a total time of more than 10 minutes, in some non-limiting embodiments less than 10 minutes, in some non-limiting embodiments less than 8 minutes, in some non-limiting embodiments less than 6 minutes, in some non-limiting embodiments 4 minutes, in some non-limiting embodiments less than 4 minutes, and in some non-limiting embodiments less than 2 minutes.

In some non-limiting embodiments of the thermal conversion process; the soft-baked coated matrix is subsequently cured at 2 pre-selected temperatures for 2 pre-selected time intervals, the latter of which may be the same or different. In some non-limiting embodiments of the thermal conversion process; the soft-baked coated matrix is subsequently cured at 3 pre-selected temperatures for 3 pre-selected time intervals, each of which of the latter of which may be the same or different. In some non-limiting embodiments of the thermal conversion process; the soft-baked coated matrix is subsequently cured at 4 pre-selected temperatures for 4 pre-selected time intervals, each of which of the latter of which may be the same or different. In some non-limiting embodiments of the thermal conversion process; the soft-baked coated matrix is subsequently cured at 5 pre-selected temperatures for 5 pre-selected time intervals, each of which of the latter of which may be the same or different. In some non-limiting embodiments of the thermal conversion process; the soft-baked coated matrix is subsequently cured at 6 pre-selected temperatures for 6 pre-selected time intervals, each of which of the latter of which may be the same or different. In some non-limiting embodiments of the thermal conversion process; the soft-baked coated matrix is subsequently cured at 7 pre-selected temperatures for 7 pre-selected time intervals, each of which of the latter of which may be the same or different. In some non-limiting embodiments of the thermal conversion process; the soft-baked coated matrix is subsequently cured at 8 pre-selected temperatures for 8 pre-selected time intervals, each of which of the latter of which may be the same or different. In some non-limiting embodiments of the thermal conversion process; the soft-baked coated matrix is subsequently cured at 9 pre-selected temperatures for 9 pre-selected time intervals, each of which of the latter of which may be the same or different. In some non-limiting embodiments of the thermal conversion process; the soft-baked coated matrix is subsequently cured at 10 pre-selected temperatures for 10 pre-selected time intervals, each of which of the latter of which may be the same or different.

In some non-limiting embodiments of the thermal conversion process; the pre-selected temperature is greater than 80° C., in some non-limiting embodiments equal to 100° C., in some non-limiting embodiments greater than 100° C., , in some non-limiting embodiments equal to 150° C., in some non-limiting embodiments greater than 150° C., , in some non-limiting embodiments equal to 200° C., in some non-limiting embodiments greater than 200° C., , in some non-limiting embodiments equal to 250° C., in some non-limiting embodiments greater than 250° C., , in some non-limiting embodiments equal to 300° C., in some non-limiting embodiments greater than 300 ° C, , in some non-limiting embodiments equal to 350° C., in some non-limiting embodiments greater than 350° C., , in some non-limiting embodiments equal to 400° C., in some non-limiting embodiments greater than 400° C., , in some non-limiting embodiments equal to 450° C., and in some non-limiting embodiments greater than 450° C.,

In some non-limiting embodiments of the thermal conversion process; one or more of the pre-selected time intervals is 2 minutes, in some non-limiting embodiments 5 minutes, in some non-limiting embodiments 10 minutes, in some non-limiting embodiments 15 minutes, in some non-limiting embodiments 20 minutes, in some non-limiting embodiments 25 minutes, in some non-limiting embodiments 30 minutes, in some non-limiting embodiments 35 minutes, in some non-limiting embodiments 40 minutes, in some non-limiting embodiments 45 minutes, in some non-limiting embodiments 50 minutes, in some non-limiting embodiments 55 minutes, in some non-limiting embodiments 60 minutes, in some non-limiting embodiments greater than 60 minutes, in some non-limiting embodiments between 2 minutes and 60 minutes, in some non-limiting embodiments between 2 minutes and 90 minutes, and in some non-limiting embodiments between 2 minutes and 120 minutes.

In some embodiments of the thermal conversion process, the method for preparing a polyimide film comprises the following steps in order: coating a liquid composition comprising a polyamic acid solution onto a matrix; soft-baking the coated matrix; treating the soft-baked coated matrix at a plurality of pre-selected temperatures for a plurality of pre-selected time intervals whereby the polyimide film exhibits properties that are satisfactory for use in electronics applications like those disclosed herein.

In some embodiments of the thermal conversion process, the method for preparing a polyimide film consists of the following steps in order: coating a liquid composition comprising a polyamic acid solution onto a matrix; soft-baking the coated matrix; treating the soft-baked coated matrix at a plurality of pre-selected temperatures for a plurality of pre-selected time intervals whereby the polyimide film exhibits properties that are satisfactory for use in electronics applications like those disclosed herein.

In some embodiments of the thermal conversion process, the method for preparing a polyimide film consists essentially of the following steps in order: coating a liquid composition comprising a polyamic acid solution onto a matrix; soft-baking the coated matrix; treating the soft-baked coated matrix at a plurality of pre-selected temperatures for a plurality of pre-selected time intervals whereby the polyimide film exhibits properties that are satisfactory for use in electronics applications like those disclosed herein.

Typically, the liquid compositions/polyimides disclosed herein are coated/cured onto a supporting glass substrate to facilitate the processing through the rest of the display making process. At some point in the process as determined by the display maker, the polyimide coating is removed from the supporting glass substrate by a mechanical or laser lift off process. These processes separate the polyimide as a film with the deposited display layers from the glass and enable a flexible format. Often, this polyimide film with deposition layers is then bonded to a thicker, but still flexible, plastic film to provide support for subsequent fabrication of the display.

There are also provided modified-thermal conversion processes wherein conversion catalysts generally cause imidization reactions to run at lower temperatures than would be possible in the absence of such conversion catalysts.

In some non-limiting embodiments, the liquid composition is converted into a polyimide film via a modified-thermal conversion process. In some non-limiting embodiments of the modified-thermal conversion process, the liquid composition further contains conversion catalysts. In some non-limiting embodiments of the modified-thermal conversion process, the liquid composition further contains conversion catalysts selected from the group consisting of tertiary amines. In some non-limiting embodiments of the modified-thermal conversion process, the liquid composition further contains conversion catalysts selected from the group consisting of tributylamine, dimethylethanolamine, isoquinoline, 1,2-dimethylimidazole, N-methylimidazole, 2-methylimidazole, 2-ethyl-4-imidazole, 3,5-dimethylpyridine, 3,4-dimethylpyridine, 2,5-dimethylpyridine, 5-methylbenzimidazole, and the like.

In some non-limiting embodiments of the modified-thermal conversion process; the conversion catalyst is present at 5 weight percent or less of the polyamic acid solution, in some non-limiting embodiments 3 weight percent or less, in some non-limiting embodiments 1 weight percent or less, and in some non-limiting embodiments 1 weight percent.

In some non-limiting embodiments of the modified-thermal conversion process, the liquid composition further contains tributylamine as a conversion catalyst. In some non-limiting embodiments of the modified-thermal conversion process, the liquid composition further contains dimethyl-ethanolamine as a conversion catalyst. In some non-limiting embodiments of the modified-thermal conversion process, the liquid composition further contains isoquinoline as a conversion catalyst. In some non-limiting embodiments of the modified-thermal conversion process, the liquid composition further contains 1,2-dimethylimidazole as a conversion catalyst. In some non-limiting embodiments of the modified-thermal conversion process, the liquid composition further contains 3,5-dimethylpyridine as a conversion catalyst. In some non-limiting embodiments of the modified-thermal conversion process, the liquid composition further contains 5-methylbenzimidazole as a conversion catalyst. In some non-limiting embodiments of the modified-thermal conversion process, the liquid composition further contains N-methylimidazole as a conversion catalyst. In some non-limiting embodiments of the modified-thermal conversion process, the liquid composition further contains 2-methylimidazole as a conversion catalyst. In some non-limiting embodiments of the modified-thermal conversion process, the liquid composition further contains 2-ethyl-4-imidazole as a conversion catalyst. In some non-limiting embodiments of the modified-thermal conversion process, the liquid composition further contains 3,4-dimethylpyridine as a conversion catalyst. In some non-limiting embodiments of the modified-thermal conversion process, the liquid composition further contains 2,5-dimethylpyridine as a conversion catalyst.

In some non-limiting embodiments of the modified-thermal conversion process; the liquid composition is coated onto the matrix such that the soft-baked thickness of the resulting film is less than 50 μm, in some non-limiting embodiments less than 40 μm, in some non-limiting embodiments less than 30 μm, in some non-limiting embodiments less than 20 μm, in some non-limiting embodiments between 10 μm and 20 μm, in some non-limiting embodiments between 15 μm and 20 μm, and in some non-limiting embodiments less than 10 μm.

In some non-limiting embodiments of the modified-thermal conversion process, the coated matrix is soft baked on a hot plate in proximity mode wherein nitrogen gas is used to hold the coated matrix just above the hot plate. In some non-limiting embodiments of the modified-thermal conversion process, the coated matrix is soft baked on a hot plate in full-contact mode wherein the coated matrix is in direct contact with the hot plate surface. In some non-limiting embodiments of the modified-thermal conversion process, the coated matrix is soft baked on a hot plate using a combination of proximity and full-contact modes.

In some non-limiting embodiments of the modified-thermal conversion process; the coated matrix is soft-baked using a hot plate set at 80° C., in some non-limiting embodiments 90° C., in some non-limiting embodiments 100° C., , in some non-limiting embodiments 110° C., , in some non-limiting embodiments 120° C., , in some non-limiting embodiments 130° C., and in some non-limiting embodiments 140° C.

In some non-limiting embodiments of the modified-thermal conversion process; the coated matrix is soft-baked for a total time of more than 10 minutes, in some non-limiting embodiments a total time of less than 10 minutes, in some non-limiting embodiments a total time of less than 8 minutes, in some non-limiting embodiments a total time of less than 6 minutes, in some non-limiting embodiments a total time of 4 minutes, in some non-limiting embodiments a total time of less than 4 minutes, and in some non-limiting embodiments a total time of less than 2 minutes.

In some non-limiting embodiments of the modified-thermal conversion process; the soft-baked coated matrix is subsequently cured at 2 pre-selected temperatures for 2 pre-selected time intervals, the latter of which may be the same or different. In some non-limiting embodiments of the modified-thermal conversion process; the soft-baked coated matrix is subsequently cured at 3 pre-selected temperatures for 3 pre-selected time intervals, each of which of the latter of which may be the same or different. In some non-limiting embodiments of the modified-thermal conversion process; the soft-baked coated matrix is subsequently cured at 4 pre-selected temperatures for 4 pre-selected time intervals, each of which of the latter of which may be the same or different. In some non-limiting embodiments of the modified-thermal conversion process; the soft-baked coated matrix is subsequently cured at 5 pre-selected temperatures for 5 pre-selected time intervals, each of which of the latter of which may be the same or different. In some non-limiting embodiments of the modified-thermal conversion process; the soft-baked coated matrix is subsequently cured at 6 pre-selected temperatures for 6 pre-selected time intervals, each of which of the latter of which may be the same or different. In some embodiments of the modified-thermal conversion process; the soft-baked coated matrix is subsequently cured at 7 pre-selected temperatures for 7 pre-selected time intervals, each of which of the latter of which may be the same or different. In some non-limiting embodiments of the modified-thermal conversion process; the soft-baked coated matrix is subsequently cured at 8 pre-selected temperatures for 8 pre-selected time intervals, each of which of the latter of which may be the same or different. In some non-limiting embodiments of the modified-thermal conversion process; the soft-baked coated matrix is subsequently cured at 9 pre-selected temperatures for 9 pre-selected time intervals, each of which of the latter of which may be the same or different. In some non-limiting embodiments of the modified-thermal conversion process; the soft-baked coated matrix is subsequently cured at 10 pre-selected temperatures for 10 pre-selected time intervals, each of which of the latter of which may be the same or different.

In some non-limiting embodiments of the modified-thermal conversion process; the pre-selected temperature is greater than 80° C., in some non-limiting embodiments equal to 100° C., in some non-limiting embodiments greater than 100 ° C, in some non-limiting embodiments equal to 150° C., in some non-limiting embodiments greater than 150° C., in some non-limiting embodiments equal to 200° C., in some non-limiting embodiments greater than 200° C., in some non-limiting embodiments equal to 220° C., in some non-limiting embodiments greater than 220° C., in some non-limiting embodiments equal to 230° C., in some non-limiting embodiments greater than 230° C., in some non-limiting embodiments equal to 240° C., in some non-limiting embodiments greater than 240° C., in some non-limiting embodiments equal to 250° C., in some non-limiting embodiments greater than 250° C., in some non-limiting embodiments equal to 260° C., in some non-limiting embodiments greater than 260° C., in some non-limiting embodiments equal to 270° C., in some non-limiting embodiments greater than 270° C., in some non-limiting embodiments equal to 280° C., in some non-limiting embodiments greater than 280° C., in some non-limiting embodiments equal to 290° C., in some non-limiting embodiments greater than 290° C., in some non-limiting embodiments equal to 300° C., in some non-limiting embodiments less than 300° C., in some non-limiting embodiments less than 290° C., in some non-limiting embodiments less than 280° C., in some non-limiting embodiments less than 270° C., in some non-limiting embodiments less than 260° C., and in some non-limiting embodiments less than 250° C.

In some non-limiting embodiments of the modified-thermal conversion process; one or more of the pre-selected time intervals is 2 minutes, in some non-limiting embodiments 5 minutes, in some non-limiting embodiments 10 minutes, in some non-limiting embodiments 15 minutes, in some non-limiting embodiments 20 minutes, in some non-limiting embodiments 25 minutes, in some non-limiting embodiments 30 minutes, in some non-limiting embodiments 35 minutes, in some non-limiting embodiments 40 minutes, in some non-limiting embodiments 45 minutes, in some non-limiting embodiments 50 minutes, in some non-limiting embodiments 55 minutes, in some non-limiting embodiments 60 minutes, in some non-limiting embodiments greater than 60 minutes, in some non-limiting embodiments between 2 minutes and 60 minutes, in some non-limiting embodiments between 2 minutes and 90 minutes, and in some non-limiting embodiments between 2 minutes and 120 minutes.

In some non-limiting embodiments of the modified-thermal conversion process, the method for preparing a polyimide film comprises the following steps in order: coating a liquid composition including a conversion chemical onto a matrix; soft-baking the coated matrix; treating the soft-baked coated matrix at a plurality of pre-selected temperatures for a plurality of pre-selected time intervals whereby the polyimide film exhibits properties that are satisfactory for use in electronics applications like those disclosed herein.

In some non-limiting embodiments of the modified-thermal conversion process, the method for preparing a polyimide film consists of the following steps in order: coating a liquid composition including a conversion chemical onto a matrix; soft-baking the coated matrix; treating the soft-baked coated matrix at a plurality of pre-selected temperatures for a plurality of pre-selected time intervals whereby the polyimide film exhibits properties that are satisfactory for use in electronics applications like those disclosed herein.

In some non-limiting embodiments of the modified-thermal conversion process, the method for preparing a polyimide film consists essentially of the following steps in order: coating liquid composition including a conversion chemical onto a matrix; soft-baking the coated matrix; treating the soft-baked coated matrix at a plurality of pre-selected temperatures for a plurality of pre-selected time intervals whereby the polyimide film exhibits properties that are satisfactory for use in electronics applications like those disclosed herein.

### 5. The Electronic Device

The polyimide films disclosed herein can be suitable for use in a number of layers in electronic display devices such as OLED and LCD Displays. Nonlimiting examples of such layers include device substrates, touch panels, substrates for color filter sheets, cover films, and others. The particular materials' properties requirements for each application are unique and may be addressed by appropriate composition(s) and processing condition(s) for the polyimide films disclosed herein. In some embodiments, the flexible replacement for glass in an electronic device is a polyimide film having the repeat unit of Formula II, as described in detail above.

Organic electronic devices that may benefit from having one or more layers including at least one compound as described herein include, but are not limited to, (1) devices that convert electrical energy into radiation (e.g., a light-emitting diode, light emitting diode display, lighting device, luminaire, or diode laser), (2) devices that detect signals through electronics processes (e.g., photodetectors, photoconductive cells, photoresistors, photoswitches, phototransistors, phototubes, IR detectors, biosensors), (3) devices that convert radiation into electrical energy, (e.g., a photovoltaic device or solar cell), (4) devices that convert light of one wavelength to light of a longer wavelength, (e.g., a down-converting phosphor device); and (5) devices that include one or more electronic components that include one or more organic semi-conductor layers (e.g., a transistor or diode). Other uses for the compositions according to the present invention include coating materials for memory storage devices, antistatic films, biosensors, electrochromic devices, solid electrolyte capacitors, energy storage devices such as a rechargeable battery, and electromagnetic shielding applications.

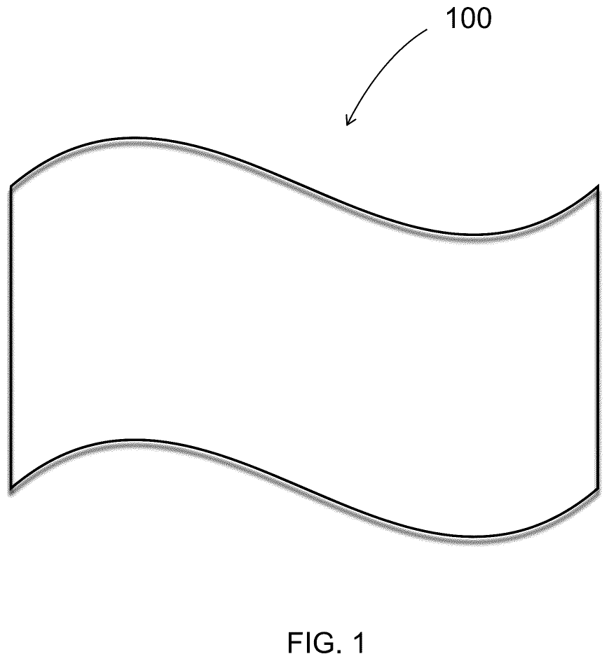

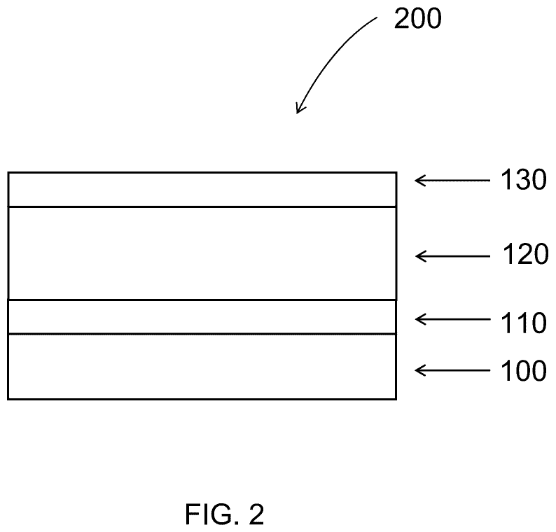

One illustration of a polyimide film that can act as a flexible replacement for glass as described herein is shown in FIG. 1. The flexible film 100 can have the properties as described in the embodiments of this disclosure. In some embodiments, the polyimide film that can act as a flexible replacement for glass is included in an electronic device. FIG. 2 illustrates the case when the electronic device 200 is an organic electronic device. The device 200 has a substrate 100, an anode layer 110 and a second electrical contact layer, a cathode layer 130, and a photoactive layer 120 between them. Additional layers may optionally be present. Adjacent to the anode may be a hole injection layer (not shown), sometimes referred to as a buffer layer. Adjacent to the hole injection layer may be a hole transport layer (not shown), including hole transport material. Adjacent to the cathode may be an electron transport layer (not shown), including an electron transport material. As an option, devices may use one or more additional hole injection or hole transport layers (not shown) next to the anode 110 and/or one or more additional electron injection or electron transport layers (not shown) next to the cathode 130. Layers between 110 and 130 are individually and collectively referred to as the organic active layers. Additional layers that may or may not be present include color filters, touch panels, and/or cover sheets. One or more of these layers, in addition to the substrate 100, may also be made from the polyimide films disclosed herein.

The different layers will be discussed further herein with reference to FIG. 2. However, the discussion applies to other configurations as well.

In some embodiments, the different layers have the following range of thicknesses: substrate 100, 5-100 microns, anode 110, 500-5000 Å, in some embodiments, 1000-2000 Å; hole injection layer (not shown), 50-2000 Å, in some embodiments, 200-1000 Å; hole transport layer (not shown), 50-3000 Å, in some embodiments, 200-2000 Å; photoactive layer 120, 10-2000 Å, in some embodiments, 100-1000 Å; electron transport layer (not shown), 50-2000 Å, in some embodiments, 100-1000 Å; cathode 130, 200-10000 Å, in some embodiments, 300-5000 Å. The desired ratio of layer thicknesses will depend on the exact nature of the materials used.

In some embodiments, the organic electronic device (OLED) contains a flexible replacement for glass as disclosed herein.

In some embodiments, an organic electronic device includes a substrate, an anode, a cathode, and a photoactive layer therebetween, and further includes one or more additional organic active layers. In some embodiments, the additional organic active layer is a hole transport layer. In some embodiments, the additional organic active layer is an electron transport layer. In some embodiments, the additional organic layers are both hole transport and electron transport layers.

The anode 110 is an electrode that is particularly efficient for injecting positive charge carriers. It can be made of, for example materials containing a metal, mixed metal, alloy, metal oxide or mixed-metal oxide, or it can be a conducting polymer, and mixtures thereof. Suitable metals include the Group 11 metals, the metals in Groups 4, 5, and 6, and the Group 8-10 transition metals. If the anode is to be light-transmitting, mixed-metal oxides of Groups 12, 13 and 14 metals, such as indium-tin-oxide, are generally used. The anode may also include an organic material such as polyaniline as described in “Flexible light-emitting diodes made from soluble conducting polymer,” Nature vol. 357, pp 477 479 (11 Jun. 1992). At least one of the anode and cathode should be at least partially transparent to allow the generated light to be observed.

Optional hole injection layers can include hole injection materials. The term “hole injection layer” or “hole injection material” is intended to mean electrically conductive or semiconductive materials and may have one or more functions in an organic electronic device, including but not limited to, planarization of the underlying layer, charge transport and/or charge injection properties, scavenging of impurities such as oxygen or metal ions, and other aspects to facilitate or to improve the performance of the organic electronic device. Hole injection materials may be polymers, oligomers, or small molecules, and may be in the form of solutions, dispersions, suspensions, emulsions, colloidal mixtures, or other compositions.

The hole injection layer can be formed with polymeric materials, such as polyaniline (PANI) or polyethylenedioxythiophene (PEDOT), which are often doped with protonic acids. The protonic acids can be, for example, poly(styrenesulfonic acid), poly(2-acrylamido-2-methyl-1-propanesulfonic acid), and the like. The hole injection layer 120 can include charge transfer compounds, and the like, such as copper phthalocyanine and the tetrathiafulvalene-tetracyanoquinodimethane system (TTF-TCNQ). In some embodiments, the hole injection layer 120 is made from a dispersion of a conducting polymer and a colloid-forming polymeric acid. Such materials have been described in, for example, published U.S. patent applications 2004-0102577, 2004-0127637, and 2005-0205860.

Other layers can include hole transport materials. Examples of hole transport materials for the hole transport layer have been summarized for example, in Kirk-Othmer Encyclopedia of Chemical Technology, Fourth Edition, Vol. 18, p. 837-860, 1996, by Y. Wang. Both hole transporting small molecules and polymers can be used. Commonly used hole transporting molecules include, but are not limited to: 4,4′,4″-tris(N,N-diphenyl-amino)-triphenylamine (TDATA); 4,4′,4″-tris(N-3-methylphenyl-N-phenyl-amino)-triphenylamine (MTDATA); N,N′-diphenyl-N,N′-bis(3-methylphenyl)-[1, 1′-biphenyl]-4,4′-diamine (TPD); 4, 4′-bis(carbazol-9-yl)biphenyl (CBP); 1,3-bis(carbazol-9-yl)benzene (mCP); 1,1-bis[(di-4-tolylamino) phenyl]cyclohexane (TAPC); N, N′-bis(4-methylphenyl)-N, N′-bis(4-ethylphenyl)-[1, 1′-(3,3′-dimethyl)biphenyl]-4,4′-diamine (ETPD);

tetrakis-(3-methylphenyl)-N,N,N′, N′-2,5-phenylenediamine (PDA); α-phenyl-4-N,N-diphenylaminostyrene (TPS); p-(diethylamino)benzaldehyde diphenylhydrazone (DEH); triphenylamine (TPA); bis[4-(N,N-diethylamino)-2-methylphenyl](4-methylphenyl)methane (MPMP); 1-phenyl-3-[p-(diethylamino)styryl]-5-[p-(diethylamino)phenyl]pyrazoline (PPR or DEASP); 1,2-trans-bis(9H-carbazol-9-yl)cyclobutane (DCZB); N,N,N′, N′-tetrakis(4-methylphenyl)-(1,1′-biphenyl)-4,4′-diamine (TTB); N,N′-bis(naphthalen-1-yl)-N,N′-bis-(phenyl)benzidine (a-NPB); and porphyrinic compounds, such as copper phthalocyanine. Commonly used hole transporting polymers include, but are not limited to, polyvinylcarbazole, (phenylmethyl)polysilane, poly(dioxythiophenes), polyanilines, and polypyrroles. It is also possible to obtain hole transporting polymers by doping hole transporting molecules such as those mentioned above into polymers such as polystyrene and polycarbonate. In some cases, triarylamine polymers are used, especially triarylamine-fluorene copolymers. In some cases, the polymers and copolymers are crosslinkable. Examples of crosslinkable hole transport polymers can be found in, for example, published US patent application 2005-0184287 and published PCT application WO 2005/052027. In some embodiments, the hole transport layer is doped with a p-dopant, such as tetrafluorotetracyanoquinodimethane and perylene-3,4,9,10-tetracarboxylic-3,4,9,10-dianhydride.

Depending upon the application of the device, the photoactive layer 120 can be a light-emitting layer that is activated by an applied voltage (such as in a light-emitting diode or light-emitting electrochemical cell), a layer of material that absorbs light and emits light having a longer wavelength (such as in a down-converting phosphor device), or a layer of material that responds to radiant energy and generates a signal with or without an applied bias voltage (such as in a photodetector or photovoltaic device).

In some non-limiting embodiments, the photoactive layer includes an emissive compound as a photoactive material. In some non-limiting embodiments, the photoactive layer further comprises a host material. Examples of host materials include, but are not limited to, chrysenes, phenanthrenes, triphenylenes, phenanthrolines, naphthalenes, anthracenes, quinolines, isoquinolines, quinoxalines, phenylpyridines, carbazoles, indolocarbazoles, furans, benzofurans, dibenzofurans, benzodifurans, and metal quinolinate complexes. In some non-limiting embodiments, the host materials are deuterated.

In some non-limiting embodiments, the photoactive layer comprises (a) a dopant capable of electroluminescence having an emission maximum between 380 and 750 nm, (b) a first host compound, and (c) a second host compound. Suitable second host compounds are described above.

In some non-limiting embodiments, the photoactive layer includes only (a) a dopant capable of electroluminescence having an emission maximum between 380 and 750 nm, (b) a first host compound, and (c) a second host compound, where additional materials that would materially alter the principle of operation or the distinguishing characteristics of the layer are not present.

In some non-limiting embodiments, the first host is present in higher concentration than the second host, based on weight in the photoactive layer.

In some non-limiting embodiments, the weight ratio of first host to second host in the photoactive layer is in the range of 10:1 to 1:10. In some non-limiting embodiments, the weight ratio is in the range of 6:1 to 1:6; in some non-limiting embodiments, 5:1 to 1:2; in some non-limiting embodiments, 3:1 to 1:1.

In some non-limiting embodiments, the weight ratio of dopant to the total host is in the range of 1:99 to 20:80; in some non-limiting embodiments, 5:95 to 15:85.

In some non-limiting embodiments, the photoactive layer comprises (a) a red light-emitting dopant, (b) a first host compound, and (c) a second host compound.

In some non-limiting embodiments, the photoactive layer comprises (a) a green light-emitting dopant, (b) a first host compound, and (c) a second host compound.

In some non-limiting embodiments, the photoactive layer comprises (a) a yellow light-emitting dopant, (b) a first host compound, and (c) a second host compound.

Optional layers can function both to facilitate electron transport, and also serve as a confinement layer to prevent quenching of the exciton at layer interfaces. In some non-limiting embodiments, this layer promotes electron mobility and reduces exciton quenching.

In some non-limiting embodiments, such layers include other electron transport materials. Examples of electron transport materials which can be used in the optional electron transport layer, include metal chelated oxinoid compounds, including metal quinolate derivatives such as tris(8-hydroxyquinolato)aluminum (AlQ), bis(2-methyl-8-quinolinolato)(p-phenylphenolato) aluminum (BAlq), tetrakis-(8-hydroxyquinolato)hafnium (HfQ) and tetrakis-(8-hydroxyquinolato)zirconium (ZrQ); and azole compounds such as 2- (4-biphenylyl)-5-(4-t-butylphenyl)-1,3,4-oxadiazole
(PBD), 3-(4-biphenylyl)-4-phenyl-5-(4-t-butylphenyl)-1,2,4-triazole (TAZ), and 1,3,5-tri(phenyl-2-benzimidazole)benzene (TPBI); quinoxaline derivatives such as 2,3-bis(4-fluorophenyl)quinoxaline; phenanthrolines such as 4,7-diphenyl-1,10-phenanthroline (DPA) and 2,9-dimethyl-4,7-diphenyl-1,10-phenanthroline (DDPA); triazines; fullerenes; and mixtures thereof. In some embodiments, the electron transport material is selected from the group consisting of metal quinolates and phenanthroline derivatives. In some embodiments, the electron transport layer further includes an n-dopant. N-dopant materials are well known. The n-dopants include, but are not limited to, Group 1 and 2 metals; Group 1 and 2 metal salts, such as LiF, CsF, and Cs₂CO₃; Group 1 and 2 metal organic compounds, such as Li quinolate; and molecular n-dopants, such as leuco dyes, metal complexes, such as W₂(hpp)₄ where hpp=1,3,4,6,7,8-hexahydro-2H-pyrimido-[1,2-a]-pyrimidine and cobaltocene, tetrathianaphthacene, bis(ethylenedithio)tetrathiafulvalene, heterocyclic radicals or diradicals, and the dimers, oligomers, polymers, dispiro compounds and polycycles of heterocyclic radical or diradicals.

An optional electron injection layer may be deposited over the electron transport layer. Examples of electron injection materials include, but are not limited to, Li-containing organometallic compounds, LiF, Li₂O, Li quinolate, Cs-containing organometallic compounds, CsF, Cs₂O, and Cs₂CO₃. This layer may react with the underlying electron transport layer, the overlying cathode, or both. When an electron injection layer is present, the amount of material deposited is generally in the range of 1-100 Å, in some embodiments 1-10 Å.

The cathode 130 is an electrode that is particularly efficient for injecting electrons or negative charge carriers. The cathode can be any metal or nonmetal having a lower work function than the anode. Materials for the cathode can be selected from alkali metals of Group 1 (e.g., Li, Cs), the Group 2 (alkaline earth) metals, the Group 12 metals, including the rare earth elements and lanthanides, and the actinides. Materials such as aluminum, indium, calcium, barium, samarium and magnesium, as well as combinations, can be used.

It is known to have other layers in organic electronic devices. For example, there can be layers (not shown) between the anode 110 and hole injection layer (not shown) to control the amount of positive charge injected and/or to provide band-gap matching of the layers, or to function as a protective layer. Layers that are known in the art can be used, such as copper phthalocyanine, silicon oxy-nitride, fluorocarbons, silanes, or an ultra-thin layer of a metal, such as Pt. Alternatively, some or all of anode layer 110, active layer 120, or cathode layer 130, can be surface-treated to increase charge carrier transport efficiency. The choice of materials for each of the component layers is preferably determined by balancing the positive and negative charges in the emitter layer to provide a device with high electroluminescence efficiency.

It is understood that each functional layer can be made up of more than one layer.

The device layers can generally be formed by any deposition technique, or combinations of techniques, including vapor deposition/PECVD, liquid deposition, and thermal transfer. Substrates such as glass, plastics, and metals can be used. Conventional vapor deposition techniques can be used, such as thermal evaporation, chemical vapor deposition, and the like.

As an alternative to vapor deposition methods, the organic layers can be applied from solutions or dispersions in suitable solvents, using conventional coating or printing techniques, including but not limited to coating, dip-coating, roll-to-roll techniques, ink-jet printing, continuous nozzle printing, screen-printing, gravure printing and the like.

For liquid deposition methods, a suitable solvent for a particular compound or related class of compounds can be readily determined by one skilled in the art. For some applications, it is desirable that the compounds be dissolved in non-aqueous solvents. Such non-aqueous solvents can be relatively polar, such as C₁ to C₂₀ alcohols, ethers, and acid esters, or can be relatively non-polar such as C₁ to C₁₂ alkanes or aromatics such as toluene, xylenes, trifluorotoluene and the like. Other suitable liquids for use in making the liquid composition, either as a solution or dispersion as described herein, including the new compounds, includes, but not limited to, chlorinated hydrocarbons (such as methylene chloride, chloroform, chlorobenzene), aromatic hydrocarbons (such as substituted and non-substituted toluenes and xylenes), including triflurotoluene), polar solvents (such as tetrahydrofuran (THP), N-methyl pyrrolidone) esters (such as ethylacetate) alcohols (isopropanol), ketones (cyclopentatone) and mixtures thereof. Suitable solvents for electroluminescent materials have been described in, for example, published PCT application WO 2007/145979.

In some non-limiting embodiments, the device is fabricated by liquid deposition of the hole injection layer, the hole transport layer, and the photoactive layer, and by vapor deposition of the anode, the electron transport layer, an electron injection layer and the cathode onto the flexible substrate.

It is understood that the efficiency of devices can be improved by optimizing the other layers in the device. For example, more efficient cathodes such as Ca, Ba or LiF can be used. Shaped substrates and novel hole transport materials that result in a reduction in operating voltage or increase quantum efficiency are also applicable. Additional layers can also be added to tailor the energy levels of the various layers and facilitate electroluminescence.

In some non-limiting embodiments, the device has the following structure, in order: substrate, anode, hole injection layer, hole transport layer, photoactive layer, electron transport layer, electron injection layer, cathode.

Although methods and materials similar or equivalent to those described herein can be used in the practice or testing of the present invention, suitable methods and materials are described below. In addition, the materials, methods, and examples are illustrative only and not intended to be limiting. All publications, patent applications, patents, and other references mentioned herein are incorporated by reference in their entirety.

### EXAMPLES

The concepts described herein will be further illustrated in the following examples, which do not limit the scope of the invention described in the claims.

### Examples

The concepts described herein will be further illustrated in the following examples, which do not limit the scope of the invention described in the claims.

### Typical Synthesis of Parent Polyamic Acid

Preparation of liquid compositions based on PMDA/6FDA//TFMB 80/20//100 in NMP. Into a 1-liter reaction flask equipped with a nitrogen inlet and outlet, mechanical stirrer and thermocouple were charged 40.0 g of TFMB (0.125 mol) and 220mL of 1-methyl-2-pyrrolidinone (NMP). The mixture was agitated under nitrogen at room temperature for about 30 minutes. Afterwards, 11.098 g (0.025 mol) of 6FDA was added slowly in portions to the stirring solution of the diamine followed by 21.251 g (0.0974 mol) of PMDA and 60mL NMP in portions. The addition rate of the dianhydrides was controlled to keep the maximum reaction temperature <30° C. After completion of the dianhydride addition, an additional 90ml of NMP was used to wash any remaining dianhydride powder from containers and the walls of the reaction flask. The resulting mixture was stirred for 7 days. Brookfield cone and plate viscometry was used to monitor the solution viscosity by removing small samples from the reaction flask for testing. The viscosity was adjusted by adding NMP and PMDA (0.001-0.0026 mol). Final viscosity of the polymer solution was 4577 cps at 25° C.

### Example 1

PMDA/6FDA//TFMB 80/20//100 with 3 wt % trihexylphosphine (THP). The liquid composition PMDA/6FDA//TFMB 80/20//100 as prepared above was mixed with 3 wt % of trihexylphosphine and in a Thinky mixer (500 rpm/30 s 101.3 kPa, 2000 rpm/90 s 30 kPa). A polyimide film (Film 1) was prepared by spin coating, then soft-baking on a hotplate (4 min at 100° C.) and cured under N₂ in an oven with O₂ level ≤50ppm. The highest curing temperature was 410° C.

### Example 2

PMDA/6FDA//TFMB 80/20//100 with 3 wt % trihexylphosphine (THP). The liquid composition PMDA/6FDA//TFMB 80/20//100 as prepared above was mixed with 3 wt % of trihexylphosphine and in a Thinky mixer (500 rpm/30 s 101.3 kPa, 2000 rpm/90 s 30 kPa). A polyimide film (Film 2) was prepared by spin coating, then soft-baking on a hotplate (4 min at 100° C.) and cured under N₂ in an oven with O₂ level ≤50 ppm. The highest curing temperature was 430° C.

### Comparative Examples 1 and 2

Comparative polyimide Films 1 and 2 were prepared from the PMDA/6FDA//TFMB 80/20//100 liquid composition as prepared above and cured in Examples 1 and 2 respectively, without the addition of trihexylphosphine (THP).

### Polyimide Film Characterization

A Hunter Lab spectrophotometer was used to measure b*, yellowness index, and % transmittance (%T) over the wavelength range 360nm-780nm. Thermal measurements on films were made using a combination of thermogravimetric analysis and thermomechanical analysis as appropriate for the specific parameters reported herein. Mechanical properties were measured using equipment from Instron.

Properties of polyimide films are reported in Table 1.

TABLE 1

| | | | Compara- | | Compara- |
|---|---|---|---|---|---|
| | | | tive | | tive |
| | Unit | Film 1 | Film 1 | Film 2 | Film 2 |
| THP/Polymer | wt % | 3 | 0 | 3 | 0 |
| Cure Temp | ° C. | 410 | 410 | 430 | 430 |
| Film Thickness | μm | 12 | 12 | 12 | 12 |
| 1.0% weight loss | ° C. | 517 | 520 | 520 | 518 |
| Temp (Td) | | | | | |
| CTE 50-350° C. | ppm/° C. | 8.7 | 7.4 | 8.7 | 7.8 |
| Modulus | GPa | 6.6 | 6.2 | 6.2 | 6.8 |
| Tensile strength | MPa | 204 | 213 | 195 | 154 |
| Elongation to | % | 22 | 25 | 22 | 18 |
| break | | | | | |
| 380-780 nm Avg. | % | 81.5 | 81.2 | 80.2 | 77.0 |
| Transmittance | | | | | |
| b* | | 7.3 | 8.8 | 9.9 | 15.2 |
| YI | | 12.1 | 14.2 | 16.0 | 24.8 |
| Haze | % | 0.1 | 0.1 | 0.1 | 0.1 |

Cure Temp = maximum cure temperature in ° C.; CTE is the second scan (50-250° C.) in ppm/° C.; Td is the temperature in ° C. at which a 1% weight loss occurs.

In all cases, the T_{g} of the films was greater than 450° C., which was the upper limit of the instrument used to measure T_{g}.

Table 1 illustrates that polyimide films prepared from liquid compositions including 3 wt % trihexylphosphine (THP) exhibit improved transparency (lower b*/YI and higher average transmittance) compared with the samples without additive. The presence of the additive does not negatively impact the other film properties measured.

### Example 3

PMDA/BPDA/6FDA//FSTD (fluoroalkyl-substituted terphenyl-diamine) 50/45/5//100 with 2 wt % bis(2,4,4-trimethylpentyl) phosphinic acid (BPA). The FSTD and liquid compositions based thereon have been described, for example, in published patent application WO 2020/219411. The liquid composition was prepared in a manner analogous to that used for the preparation of the Parent Polyamic Acid associated with Examples 1 and 2 above. The polyimide film (Film 3) was prepared by spin coating, then soft-baking on hotplate (4min at 100° C.) and curing in N₂ oven with O₂ level ≤50ppm. The highest curing temperature was 450° C.

### Example 4

PMDA/BPDA/6FDA//FSTD/TFMB (fluoroalkyl-substituted terphenyl-diamine) 50/45/5//50/50 with 2 wt % bis(2,4,4-trimethylpentyl) phosphinic acid (BPA). The FSTD and liquid composition based thereon have been described, for example, in published patent application WO 2020/219411. The liquid composition was prepared in a manner analogous to that used for the preparation of the Parent Polyamic Acid associated with Examples 1 and 2 above. The polyimide film (Film 4) was prepared by spin coating, then soft-baking on hotplate (4 min at 100° C.) and curing in N ₂ oven with O₂ level ≤50ppm. The highest curing temperature was 450° C.

### Comparative Examples 3 and 4

Comparative polyimide Films 3 and 4 were prepared from the liquid compositions as prepared above and cured in Examples 3 and 4 respectively, without the addition of bis(2,4,4-trimethylpentyl) phosphinic (BPA).

Properties of polyimide films are measured as above and are reported in Table 2.

TABLE 2

| | | | Compara- | | Compara- |
|---|---|---|---|---|---|
| | | | tive | | tive |
| | Unit | Film 3 | Film 3 | Film 4 | Film 4 |
| BPA/Polymer | wt % | 2 | 0 | 2 | 0 |
| Cure Temp | ° C. | 450 | 450 | 450 | 450 |
| Film Thickness | μm | 10 | 10 | 12 | 12 |
| 1.0% weight loss | ° C. | 534 | 534 | 540 | 539 |
| Temp (Td) | | | | | |
| CTE 50-350° C. | ppm/° C. | 13.3 | 27.5 | 8.5 | 22.1 |
| Modulus | GPa | 5.7 | 5.8 | 5.3 | 6.0 |
| Tensile strength | MPa | 176 | 197 | 162 | 190 |
| Elongation to | % | 16 | 23 | 17 | 20 |
| break | | | | | |
| 380-780 nm Avg. | % | 85.3 | 82.8 | 81.8 | 77.7 |
| Transmittance | | | | | |
| b* | | 3.8 | 5.6 | 7.5 | 10.3 |
| YI | | 6.4 | 9.7 | 12.6 | 17.9 |
| Haze | % | 0.1 | 0.9 | 0.2 | 1.1 |

Cure Temp = maximum cure temperature in ° C.; CTE is the second scan (50-250° C.) in ppm/° C.; Td is the temperature in ° C. at which a 1% weight loss occurs.

Table 2 illustrates that samples with bis(2,4,4-trimethylpentyl) phosphinic acid additive show improved transparency (lower b*/YI and higher transmittance) compared with the samples without additive. A reduction is CTE is also observed with addition of bis(2,4,4-trimethylpentyl) phosphinic acid.

### Examples 5-10

BPDA/6FDA//FSTD (fluoroalkyl-substituted terphenyl-diamine) 98/2//100 with varying amounts of trihexylphosphine oxide (THPO), di-n-hexylphosphinous acid (DHPA), and hexyldihexyl phosphinate (HDHP) as indicated in Table 3. The FSTD and liquid composition based thereon have been described, for example, in published patent application WO 2020/219411. The liquid composition was prepared in a manner analogous to that used for the preparation of the Parent Polyamic Acid associated with Examples 1 and 2 above. The polyimide films (Films 5-10) were prepared by spin coating, then soft-baking on hotplate (4min at 100° C.) and curing in N₂ oven with O₂ level ≤50ppm. The highest curing temperature was 450° C. Comparative Film 5 was prepared from a liquid composition containing no phosphorous-containing additive.

Properties of polyimide films are measured as above and are reported in Table 3.

TABLE 3

| | | Additive/ | | | | |
|---|---|---|---|---|---|---|
| Example | Additive | Polymer | Thickness(μm) | Tr % | b* | YI |
| Comparative | | 0 | 10.1 | 80.8 | 6.7 | 12.9 |
| Film 5 | | | | | | |
| Film 5 | Mixture | 3% | 10.1 | 86.6 | 2.8 | 5.0 |
| Film 6 | of THPO, | 5% | 10.2 | 86.8 | 2.5 | 4.3 |
| Film 7 | DHPA | 7% | 10.4 | 86.9 | 2.3 | 4.1 |
| Film 8 | and | 10% | 10.3 | 87.1 | 2.2 | 3.9 |
| | HDHP | | | | | |
| Film 9 | THPO | 3% | 9.7 | 84.1 | 4.6 | 8.6 |
| Film 10 | DHPA | 3% | 10.1 | 85.2 | 4.0 | 7.2 |

Tr % = 380-780 nm Avg. Transmittance.

Table 3 illustrates that samples with phosphorous-containing additives, and mixtures of additives, show improved transparency (lower b*/YI and higher transmittance) compared with the samples without additive.

### Example 11

PMDA/BPDA/6FDA//TFMB 40/40/20//100 with 2 wt % bis(2,4,4-trimethylpentyl) phosphinic acid (BPA). Into a 1-liter reaction flask equipped with a nitrogen inlet and outlet, mechanical stirrer and thermocouple were charged 30.0 g of TFMB (0.0937 mol) and 142 mL of 1-methyl-2-pyrrolidinone (NMP). The mixture was agitated under nitrogen at room temperature (25° C.) for about 20 minutes to obtain a colorless solution. Afterwards, 8.323 g (0.0187 mol) of 6FDA was added slowly in portions with 50 mL NMP to the stirring solution of the diamine followed by 11.025 g (0.0375 mol) of sBPDA and 50 mL NMP in portions. Finally, 7.765 g (0.0356 mol) of PMDA was added slowly in portions to the stirring solution. The addition rate of the dianhydrides was controlled to keep the maximum reaction temperature <28° C. After completion of the dianhydride addition, an additional 50 mL of NMP was used to wash in any remaining dianhydride powder from containers and the walls of the reaction flask, and the resulting mixture was stirred for 7 days. Brookfield cone and plate viscometry was used to monitor the solution viscosity by removing small samples from the reaction flask for testing. The viscosity was adjusted by adding NMP and PMDA (0.001-0.0017 mol). Final viscosity of the polymer solution was 4874 cps at 25° C.

Example 11 includes 2 wt % of bis(2,4,4-trimethylpentyl) phosphinic acid in the above composition which was added and mixed by a Thinky mixer (500 rpm/30 s 101.3 kPa, 2000 rpm/90 s 30 kPa). The polyimide film (Film 11) was prepared by spin coating, then soft-baking on hotplate (4 min at 100° C.) and curing in N₂ oven with O₂ level ≤50 ppm. The highest curing temperature is 450° C.

Comparative Example 11 was prepared similarly, without the addition of bis(2,4,4-trimethylpentyl) phosphinic acid to generate Comparative Film 11.

Films were characterized as described above, and results are presented in Table 4.

TABLE 4

| | | | Comparative |
|---|---|---|---|
| | Unit | Film 11 | Film 11 |
| BPA/Polymer | wt % | 2 | 0 |
| Cure Temp | ° C. | 450 | 450 |
| Film Thickness | μm | 10 | 10 |
| 1.0% weight loss | ° C. | 519 | 522 |
| Temp (Td) | | | |
| CTE 50-350 | ppm/° C. | 24.5 | 30.9 |
| Modulus | GPa | 4.9 | 5.2 |
| Tensile strength | MPa | 181 | 158 |
| Elongation to | % | 27 | 16 |
| break | | | |
| 380-780 nm Avg. | % | 83.8 | 80.9 |
| Transmittance | | | |
| b* | | 4.0 | 9.9 |
| YI | | 6.7 | 15.9 |
| Haze | % | 0.4 | 0.3 |

Cure Temp = maximum cure temperature in ° C.; CTE is the second scan (50-250° C.) in ppm/° C.; Td is the temperature in ° C. at which a 1% weight loss occurs.

Table 4 illustrates that samples with bis(2,4,4-trimethylpentyl) phosphinic acid additive show improved transparency (lower b*/YI and higher transmittance) compared with the samples without additive. A reduction is CTE is also observed with addition of bis(2,4,4-trimethylpentyl) phosphinic acid.

### Examples 12-13

Amber polyamic acid compositions BPDA//PPD (100//100) (Example 12) and PMDA/BPDA//PPD (60/40//100) (Example 13) were prepared as disclosed in, for example, U.S. patent application 2008-0044639 A1. Example 12 includes 3 wt % of triphenylphosphine (TPP) in BPDA//PPD (100//100), and Example 13 includes 3 wt % of triphenylphosphine (TPP) in PMDA/BPDA//PPD (60/40//100). TPP in these compositions was added and mixed by a Thinky mixer (500 rpm/30 s 101.3 kPa, 2000 rpm/90 s 30 kPa). The polyimide films were prepared by spin coating, then soft-baking on hotplate (4min at 100° C.) and curing in N₂ oven with O₂ level ≤50ppm. The highest curing temperature in each case was 475° C. The corresponding comparative examples were prepared without the addition of TPP. Films were characterized as described above, and results are presented in Table 5.

TABLE 5

| | | | Compara- | | Compara- |
|---|---|---|---|---|---|
| | | | tive | | tive |
| | Unit | Film 12 | Film 12 | Film 13 | Film 13 |
| TPP/Polymer | wt % | 3 | 0 | 3 | 0 |
| Cure Temp | ° C. | 475 | 475 | 475 | 475 |
| Film Thickness | μm | 10 | 10 | 10 | 10 |
| CTE 50-350 | ppm/° C. | 2 | 3 | 1.4 | 0.8 |
| YI | | 39 | 38 | 92 | 71 |

Cure Temp = maximum cure temperature in ° C.; CTE is the second scan (50-350° C.) in ppm/° C.

Table 5 illustrates that improvements in thermal and optical properties realized from the addition of a TPP additive into compositions for amber polyimide films can be more modest than those realized for compositions leading to clear polyimide films, if improvements are realized at all.

### Examples 14-51

The polyamic acid liquid composition of Example 3 was prepared as described above and by substituting the phosphorous-containing additives presented in Table 6 for bis(2,4,4-trimethylpentyl) phosphinic acid. All phosphorous-containing additives were used at 3 wt %. Polyimide films were prepared by spin coating, then soft-baking on hotplate (4min at 100° C.) and curing in N₂ oven with O₂ level ≤50ppm. The highest curing temperature was 430° C.

Table 6 reports the additive used in each example, the percent (%) change in coefficient of thermal expansion (CTE) relative to the parent polyimide, and the percent (%) change in yellowness index (YI) relative to the parent polyimide.

TABLE 6

| | | % Change in CTE | % Change in YI |
|---|---|---|---|
| Example/ | | Relative to | (10 μm film) Relative |
| Film | Additive | Parent Polyimide | to Parent Polyimide |
| 14 | Di(2-ethylhexyl)phosphate | −46% | 237% |
| 15 | Triethyl Phosphate | 8% | 5% |
| 16 | 9,10-Dihydro-9-oxa-10- | −12% | 26% |
| | phosphaphenanthrene-10-oxide | | |
| 17 | Bis(2,4,4-trimethylpentyl) | −42% | −8% |
| | phosphinic acid | | |
| 18 | Diphenylphosphinic Acid | −29% | 14% |
| 19 | DiPhenylphosphinic Acid | −32% | 14% |
| | Anhydride | | |
| 20 | 1,2-Bis(di-2- | −54% | 180% |
| | pyridylphosphino)ethane | | |
| 21 | tert-butyl diphenyl phosphine | −27% | −7% |
| 22 | Ethylenebis(diphenylphosphine) | −31% | 12% |
| 23 | 1,3-Bis(diphenylphosphino) | −23% | 16% |
| | propane | | |
| 24 | 2-(Diphenylphosphino) biphenyl | −35% | −3% |
| 25 | 2,2′- | −44% | 29% |
| | Bis(diphenylphosphino)biphenyl | | |
| 26 | 4,6-Bis(diphenyl phosphino) | −52% | 143% |
| | phenoxazine | | |
| 27 | 2-Dicyclohexylphosphino-2′,6′- | −19% | 68% |
| | dimethoxybiphenyl | | |
| 28 | rac-2-(Di-tert-butylphosphino)- | −54% | 21% |
| | 1,1′-binaphthyl | | |
| 29 | 9,9-Dimethyl-4,5-bis(di-tert- | −77% | 409% |
| | butylphosphino)xanthene | | |
| 30 | (Di-tert-butylphosphino) | −33% | −7% |
| | biphenyl | | |
| 31 | 2-Di-tert-butylphosphino-2′- | −47% | 47% |
| | (N,N-dimethylamino)biphenyl | | |
| 32 | Trioctylphosphine | −28% | 17% |
| 33 | Trihexylphosphine | −30% | 39% |
| 34 | (2R,2′R,5R,5′R)-1,1′-(1,2- | −38% | 217% |
| | Ethanediyl)bis[2,5- | | |
| | diphenylphospholane] | | |
| 35 | Bis[(2-diphenyl phosphino) | −43% | 22% |
| | phenyl]ether | | |
| 36 | Triphenylphosphine | −26% | 18% |
| 37 | Tri-1-napthylenylphosphine | −24% | 9% |
| 38 | 4,6-Bis(diphenyl | −36% | 21% |
| | phosphino)dibenzofuran | | |
| 39 | Diphenyl-4-pyrenylphosphine | −17% | 10% |
| 40 | 2,2′-Bis(diphenylphosphino) | −55% | 46% |
| | benzophenone | | |
| 41 | 4,5-Bis(diphenylphosphino)-9,9- | −53% | 110% |
| | dimethylxanthene | | |
| 42 | Trioctylphosphine Oxide | −34% | 15% |
| 43 | Triethylphosphine Oxide | −33% | −8% |
| 44 | Triphenylphosphine Oxide | −23% | −3% |
| 45 | 9,10-Dihydro-9-oxa-10- | −43% | 109% |
| | phosphaphenanthrene 10- | | |
| | Oxide | | |
| 46 | Tris(2,4-di-t-butylphenyl) | −8% | −6% |
| | phosphite | | |
| 47 | Dioctyl Phenylphosphonate | −42% | 84% |
| 48 | Diethyl 1-Octylphosphonate | −38% | 90% |
| 49 | Diphenyl Phenylphosphonate | −16% | −7% |
| 50 | Tetrakis(2,4-di-tert-butylphenyl) | −38% | 70% |
| | [1,1′-biphenyl]-4,4′- | | |
| | diylbis(phosphonite) | | |
| 51 | Dimethyl Phenylphosphonite | −21% | 196% |

Table 6 illustrates that 3 wt % of the phosphorous-containing additives listed therein can be used to generate polyimide films with superior thermal properties (lower CTE), superior optical properties (lower YI), or both.

### Examples 52-58

The polyamic acid liquid compositions reported in Table 7 were prepared as in the Examples above, and in all cases 3 wt % of (di-tert-butylphosphino) biphenyl additive was added. Polyimide films were prepared by spin coating, then soft-baking on hotplate (4min at 100° C.) and curing in N₂ oven with O₂ level ≤50ppm using conditions reported in Table 6.

Table 7 reports the composition used in each example, the cure temperature and time, the percent (%) change in coefficient of thermal expansion (CTE) relative to the parent polyimide, and the percent (%) change in yellowness index (YI) relative to the parent polyimide.

TABLE 7

| Exam- | | | % Change in | % Change in |
|---|---|---|---|---|
| ple/ | | Cure | CTE relative | YI relative |
| Film | Composition | Conditions | to parent PI | to parent PI |
| 52 | 6FDA//TFMB | 320° C./60 min | −13% | −1% |
| 53 | 6FDA//TFMB | 430° C./5 min | 2% | −19% |
| 54 | 6FDA//PPD | 430° C./5 min | −3% | 26% |
| 55 | BPDA//TFMB | 430° C./5 min | −23% | −16% |
| 56 | BPDA//FSTD | 430° C./5 min | −21% | −12% |
| 57 | PMDA//TFMB | 430° C./5 min | 40% | −16% |
| 58 | PMDA//FSTD | 430° C./5 min | 20% | −4% |

Table 7 illustrates that 3 wt % of (di-tert-butylphosphino) biphenyl additive can be used to generate a variety of polyimide films with superior thermal properties (lower CTE), superior optical properties (lower YI), or both.

### Example 59

BPDA/PMDA/ODPA/6FDA//FSTD/CHDA 45/50/10/5//95/5 with 3 wt % trihexylphosphine was prepared in a manner analogous to those described herein above. A polyimide film was prepared by spin coating, then soft-baking on hotplate (4min at 100° C.) and curing in N₂ oven with O₂ level ≤50ppm at a temperature of 430° C. for 5 minutes. The film prepared from the liquid composition including the phosphorous-containing additive is observed to exhibit a reduction of 24% in CTE and a reduction of 15% in yellowness index compared to analogous films prepared without trihexylphosphine.

### Example 60

BPDA/PMDA/6FDA//FSTD/CHDA 40/55/5//95/5 with 3 wt % trihexylphosphine was prepared in a manner analogous to those described herein above. A polyimide film was prepared by spin coating, then soft-baking on hotplate (4 min at 100° C.) and curing in N₂ oven with O₂ level ≤50 ppm at a temperature of 430° C. for 5 minutes. The film prepared from the liquid composition including the phosphorous-containing additive is observed to exhibit a reduction of 27% in CTE and a reduction of 9% in yellowness index compared to analogous films prepared without trihexylphosphine.

### Examples 61 and 62

In the Examples above, the phosphorous-containing additives were introduced into the liquid compositions after the dianhydrides and diamines were introduced into the reaction vessels and caused to react. This example illustrates that polyimide film properties benefits (thermal, optical, other) can also be realized when the phosphorous-containing additive is added to the reaction solvent prior to the addition of the dianhydride and diamine.

The polyimide is based on a polyamic acid solution with composition PMDA/BPDA/6FDA //FSTD 50/45/5//100 in NMP. The additive is 0.2% trihexylphosphine, and the composition was prepared as follows. In glovebox, a 500 ml bottle was charged with 400 g 1-methyl-2-pyrrolidinone (NMP) and 0.80 g trihexylphosphine (THP) and the resulting 0.2% solution stirred at room temperature for 72 hours. This solution was used in the following polymerization.

A 500 mL reactor equipped with nitrogen inlet and outlet, mechanical stirrer, and internal thermocouple was charged with 160 g of the 0.2% THP/NMP solution under nitrogen atmosphere, followed by 33.62 g of FSTD and the mixture stirred at room temperature for approximately 15 minutes. Afterwards, 8.36g of 3,3′4,4′- biphenyl tetracarboxylic dianhydride (BPDA) was slowly added to the reaction, followed by 1.40 g of 4,4′-(hexafluoroisopropylidene)diphthalic anhydride (6FDA). After 10 minutes of stirring, 6.61 g of pyromellitic dianhydride (PMDA) was added in portions, keeping the reaction temperature under 30° C. An additional 40.0 g of THP solution was then used to wash down any monomer powder residue from the containers and the walls of the reaction flask. After 24 hours stirring at room temperature, additional PMDA (0.206 g) was added to increase the molecular weight of the polymer. A Brookfield cone and plate viscometer was used to monitor the solution viscosity by removing small samples from the reaction flask at regular intervals for testing. The mixture was stirred for an additional 80 hours at room temperature for polymer equilibration. The polymer solution was twice diluted during this time with the 0.2% THP/NMP solution (total of 80.5 g added) to lower the polymer viscosity. Final viscosity of the polymer solution was 11,730 cP at 25° C.

Table 8 shows comparison of PI film (cured at 430° C.) for samples that were treated with trihexylphosphine at the start of the polymerization (pre-treatment) versus at the end of the polymerization (post-treatment).

TABLE 8

| Exam- | | % change in | % change in |
|---|---|---|---|
| ple/ | | CTE relative | YI relative |
| Film | Treatment method | to parent PI | to parent PI |
| 61 | Post treatment (addition | −16 | −21 |
| | of 1% trihexylphosphine | | |
| | after PAA polymerization) | | |
| 62 | Pre-treatment (addition | −28 | −15 |
| | of 1% trihexylphosphine | | |
| | after PAA polymerization) | | |

Table 8 illustrates that thermal and optical properties can be improved via addition of phosphorous-containing additives, irrespective of whether the additives are introduced before or after polyamic acid polymerization.

### Examples 63-72

The polyamic acid liquid composition of Example 3 and Examples 14-51 was prepared as described above except that (di-tert-butyl phosphino)biphenyl was used as the phosphorous-containing additive. Additive loading for each Example is reported in Table 9. Polyimide films were prepared by spin coating, then soft-baking on hotplate (4 min at 100° C.) and curing in N₂ oven with O₂ level ≤50 ppm for the durations and temperatures reported in Table 9.

Table 9 further reports the percent (%) change in coefficient of thermal expansion (CTE) relative to the parent polyimide between 100° C. and 350° C., and the percent (%) change in yellowness index (YI) relative to the parent polyimide.

TABLE 9

| | | | | % Change in | % Change in |
|---|---|---|---|---|---|
| Example/ | Additive | | Cure | CTE relative | YI relative |
| Film | Loading | | Conditions | to parent PI | to parent PI |
| 63 | 2 | wt % | 410° C./6 min | −39% | −3% |
| 64 | 3 | wt % | 410° C./6 min | 47% | −6% |
| 65 | 4 | wt % | 410° C./6 min | −51% | 1% |
| 66 | 4.74 | wt % | 410° C./6 min | −52% | −2% |
| 67 | 6 | wt % | 410° C./6 min | −51% | 1% |
| 68 | 2 | wt % | 430° C./5 min | −28% | −30% |
| 69 | 3 | wt % | 430° C./5 min | −34% | −29% |
| 70 | 4 | wt % | 430° C./5 min | −37% | −30% |
| 71 | 4.74 | wt % | 430° C./5 min | −38% | −31% |
| 72 | 6 | wt % | 430° C./5 min | −43% | −32% |

### Examples 73-75

The polyamic acid liquid composition of Examples 63-72 was prepared as described above except that trihexylphosphine was used as the phosphorous-containing additive. Additive loading for each Example is reported in Table 10. Polyimide films were prepared by spin coating, then soft-baking on hotplate (4min at 100° C.) and curing in N₂ oven with O₂ level ≤50 ppm for the durations and temperatures reported in Table 10. Table 10 further reports the percent (%) change in coefficient of thermal expansion (CTE) relative to the parent polyimide between 100° C. and 350° C., and the percent (%) change in yellowness index (YI) relative to the parent polyimide.

TABLE 10

| Exam- | | | % Change in | % Change in |
|---|---|---|---|---|
| ple/ | Additive | Cure | CTE relative | YI relative |
| Film | Loading | Conditions | to parent PI | to parent PI |
| 73 | 3 wt % | 410° C./3 min | −29% | 19% |
| 74 | 4 wt % | 410° C./3 min | −41% | 35% |
| 75 | 6 wt % | 410° C./3 min | −49% | 59% |

### Examples 76-78

The polyamic acid liquid composition of Example 4 was prepared as described above except that trihexylphosphine was used as the phosphorous-containing additive. Additive loading for each Example is reported in Table 11. Polyimide films were prepared by spin coating, then soft-baking on hotplate (4min at 100° C.) and curing in N₂ oven with O₂ level ≤50 ppm for the durations and temperatures reported in Table 11. Table 11 further reports the percent (%) change in coefficient of thermal expansion (CTE) relative to the parent polyimide between 100° C. and 350° C., and the percent (%) change in yellowness index (YI) relative to the parent polyimide.

TABLE 11

| Exam- | | | % Change in | % Change in |
|---|---|---|---|---|
| ple/ | Additive | Cure | CTE relative | YI relative |
| Film | Loading | Conditions | to parent PI | to parent PI |
| 76 | 3 wt % | 410° C./5 min | −51% | 46% |
| 77 | 4 wt % | 410° C./5 min | −59% | 58% |
| 78 | 6 wt % | 410° C./5 min | −54% | 62% |

Tables 6-11 illustrate that thermal and optical properties of the polyimide films disclosed herein can be tuned through consideration of polyamic acid solution composition, phosphorous-containing additive selection and loading, and cure conditions. Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. The use of numerical values in the various ranges specified herein is stated as approximations as though the minimum and maximum values within the stated ranges were both being preceded by the word “about.” In this manner, slight variations above and below the stated ranges can be used to achieve substantially the same results as values within the ranges. Also, the disclosure of these ranges is intended as a continuous range including every value between the minimum and maximum average values including fractional values that can result when some of components of one value are mixed with those of different value. Moreover, when broader and narrower ranges are disclosed, it is within the contemplation of this invention to match a minimum value from one range with a maximum value from another range and vice versa.

What is claimed is:

1. A liquid composition comprising
(a) a polyamic acid having a repeat unit structure of Formula I 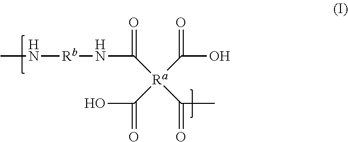
wherein:
R^{a} is the same or different at each occurrence and represents one or more tetracarboxylic acid component residues; and
R^{b} is the same or different at each occurrence and represents one or more diamine component residues;
(b) one or more phosphorous-containing additives; and
(c) a high-boiling aprotic solvent.

2. The liquid composition of claim 1, wherein the one or more phosphorous-containing additives is selected from the group consisting of phosphates, phosphinates, phosphines, phosphine oxides, phosphites, phosphonates, phosphonites, and the like and combinations thereof.

3. The liquid composition of claim 2, wherein the one or more phosphorous-containing additives is selected from the group consisting of di(2-ethylhexyl)phosphate, 9,10-dihydro-9-oxa-10-phosphaphenanthrene-10-oxide, bis(2,4,4-trimethylpentyl) phosphinic acid, trioctylphosphine, bis[(2-diphenyl phosphino)phenyl]ether, 1,3-bis(diphenylphosphino) propane, 2-dicyclohexylphosphino-2′,6′-dimethoxybiphenyl, triphenylphosphine, rac-2-(di-tert-butylphosphino)-1,1′-binaphthyl, 2-(diphenylphosphino)biphenyl, 2,2′-bis(diphenyl phosphino)biphenyl, 1,2-bis(di-2-pyridylphosphino) ethane, 4,6-bis(diphenyl phosphino) phenoxazine, 9,9-dimethyl-4,5-bis(di-tert-butylphosphino)xanthene, (di-tert-butylphosphino)biphenyl, tri-hexylphosphine, tri-1-napthylenyl phosphine, 2-di-tert-butylphosphino-2′-(N,N-dimethylamino)biphenyl, tert-butyl diphenyl phosphine, trioctyl-phosphine oxide, triphenylphosphine oxide, triethylphosphine oxide, 9,10-dihydro-9-oxa-10-phospha phenanthrene 10-oxide, tris(2,4-di-t-butylphenyl)phosphite, diphenyl phenylphosphonate, dioctyl phenyl-phosphonate, diethyl 1-octylphosphonate, tetrakis(2,4-di-tert-butylphenyl) [1,1′-biphenyl]-4,4′-diylbis (phosphonite), and the like and combinations thereof.

4. A polyimide film comprising a repeat unit structure of Formula II 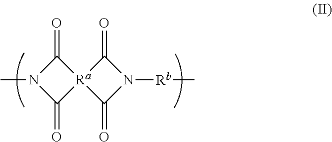
wherein:
R^{a} is the same or different at each occurrence and represents one or more tetracarboxylic acid component residues; and
R^{b} is the same or different at each occurrence and represents one or more diamine residues;
and further wherein:
the polyimide film is prepared according to a method comprising the following steps in order and without repeating:
coating a polyamic acid solution comprising one or more tetracarboxylic acid components, one or more diamine components, and one or more phosphorous-containing additives in a high-boiling, aprotic solvent onto a matrix;
soft-baking the coated matrix;
treating the soft-baked coated matrix at a plurality of pre-selected temperatures for a plurality of pre-selected time intervals.

5. The polyimide film of claim 4, wherein the polyamic acid solution comprising one or more tetracarboxylic acid components, one or more diamine components, and one or more phosphorous-containing additives in a high-boiling, aprotic solvent is prepared according to a method of first adding the phosphorous-containing additive into the high-boiling, aprotic solvent and agitating the resulting solution for a pre-selected time interval before adding the one or more tetracarboxylic acid components and the one or more diamine components.

6. The polyimide film of claim 4, wherein the polyamic acid solution comprising one or more tetracarboxylic acid components, one or more diamine components, and one or more phosphorous-containing additives in a high-boiling, aprotic solvent is prepared according to a method of first adding the one or more tetracarboxylic acid components and the one or more diamine components to the high-boiling, aprotic solvent; allowing the formation of the polyamic acid solution, and then introducing the one or more phosphorous-containing additives to the polyamic acid solution.

7. The polyimide film of claim 4, wherein a maximum of the pre-selected temperatures is greater than or equal to 400° C.

8. The polyimide film of claim 7, wherein the method is performed in an inert atmosphere.

9. The polyimide film of claim 8, wherein the film has a CTE less than 10 ppm/° C., a b* less than 5, a yellowness index less than 8, and an average transmittance greater than 85% between 380 nm and 780 nm.

10. An electronic device wherein a polyimide film having a repeat unit of Formula II according to claim 4 is used in device components selected from the group consisting of device substrates, substrates for color filter sheets, cover films, and touch screen panels.
